(19) United States
(12) Patent Application Publication
(10) Pub. No.: US 2026/0293636 A1
(43) Pub. Date: Sep. 24, 2026

(54) INTERCONNECT STRUCTURE INCLUDING ALIGNED INTERCONNECT LAYERS AND METHOD FOR MANUFACTURING THE SAME

(71) Applicant: TAIWAN SEMICONDUCTOR MANUFACTURING COMPANY, LTD., Hsinchu (TW)

(72) Inventors: Shao-Kuan LEE, Hsinchu (TW); Kuang-Wei YANG, Hsinchu (TW); Cheng-Chin LEE, Hsinchu (TW); Hsin-Yen HUANG, Hsinchu (TW); Hsiao-Kang CHANG, Hsinchu (TW)

(73) Assignee: TAIWAN SEMICONDUCTOR MANUFACTURING COMPANY, LTD., Hsinchu (TW)

(21) Appl. No.: 19/086,564

(22) Filed: Mar. 21, 2025

(51) Int. Cl. H01L 21/768; H01L 23/522; H01L 23/532

(52) U.S. Cl. CPC H10W 20/084; H10W 20/034; H10W 20/42; H10W 20/47

(57) ABSTRACT

A method for manufacturing an interconnect structure includes: forming a lower interconnect layer over a base structure, the lower interconnect layer including a lower dielectric feature and a lower conductive feature disposed in the lower dielectric feature; forming a dielectric layer on one of the lower conductive feature and the lower dielectric feature, while the other one of the lower conductive feature and the lower dielectric feature is exposed from the dielectric layer, a material of the dielectric layer being different from a material of the lower dielectric feature; after forming the dielectric layer, forming an upper dielectric feature over the lower interconnect layer to cover the dielectric layer; performing a patterning process to form a trench in the upper dielectric feature, to etch the dielectric layer, and to expose an upper surface of the lower conductive feature; and forming an upper conductive feature in the trench.

### BACKGROUND

Single damascene and dual damascene are semiconductor fabrication techniques that are used for creating interconnections between integrated circuit components. In single damascene, a trench is etched and then filled with metal (typically copper (Cu)) to form a single conductive line or via. Dual damascene is a more advanced method and is commonly used for multi-layered circuits. Both techniques are crucial for producing the fine-scale wiring essential for advanced semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing an interconnect structure in accordance with some embodiments.

FIG. 2 is a schematic view illustrating a plurality of levels in a semiconductor structure in accordance with some embodiments.

FIGS. 3 to 50 are schematic views illustrating intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

The term “source/drain region(s)” may refer to a source or a drain, individually or collectively dependent upon the context.

As transistor and conductive feature pitch scale down, manufacturers are faced with several challenges. First, as conductive features (e.g., metal lines and/or metal vias) become narrower, the material's resistivity increases. At the same time, when conductive features shrink in size, it is difficult to keep resistance of the conductive features low. The conductive features in an interconnect structure are commonly made of copper (Cu), and barriers in the interconnect structure are commonly made of tantalum nitride (TaN), which has higher resistance than Cu. As pitch scales down, a proportion of the barriers increases while a proportion of the conductive features decreases, thereby causing higher resistance. In addition, when the conductive features shrink, an aspect ratio of trenches generated during a dual damascene process increases, which leads to trench-filling difficulties. Moreover, when metal vias land on metal lines with dense pitch during a single damascene process or the dual damascene process, an overlay shift is likely to occur during the processes. The overlay shift may lead to undesirable parasitic capacitance that causes leakage currents. These challenges have to be overcome to prevent slower signal propagation, greater power consumption, and potential reliability concerns in advanced semiconductor devices. Therefore, the present disclosure is directed toward methods for manufacturing an interconnect structure, in which capacitance effect is mitigated and problems during dimension scaling are solved.

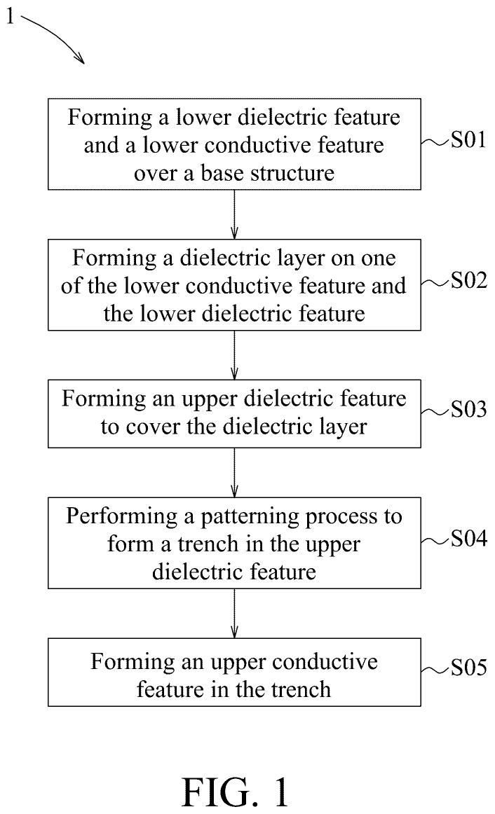

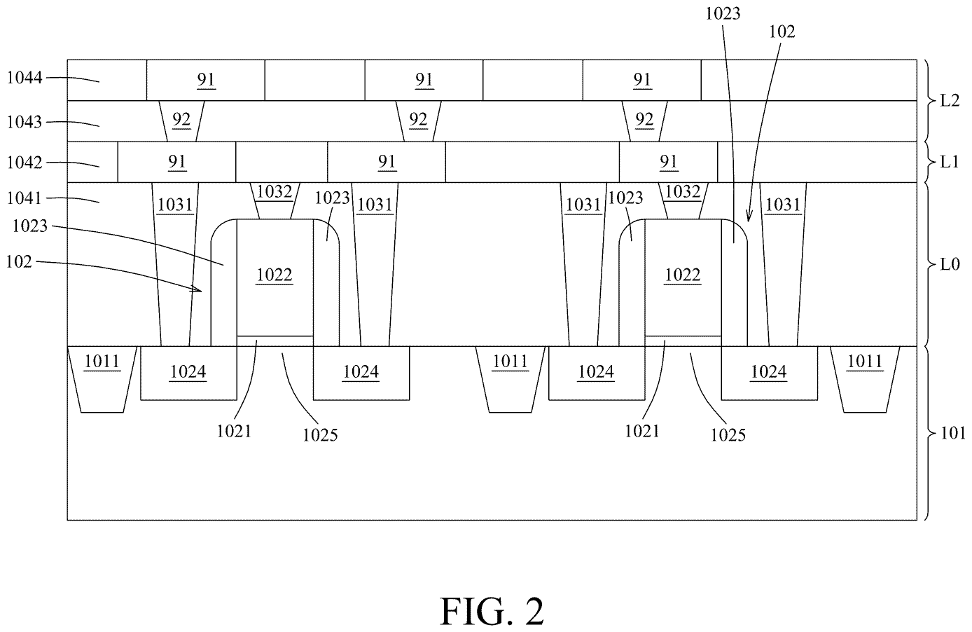

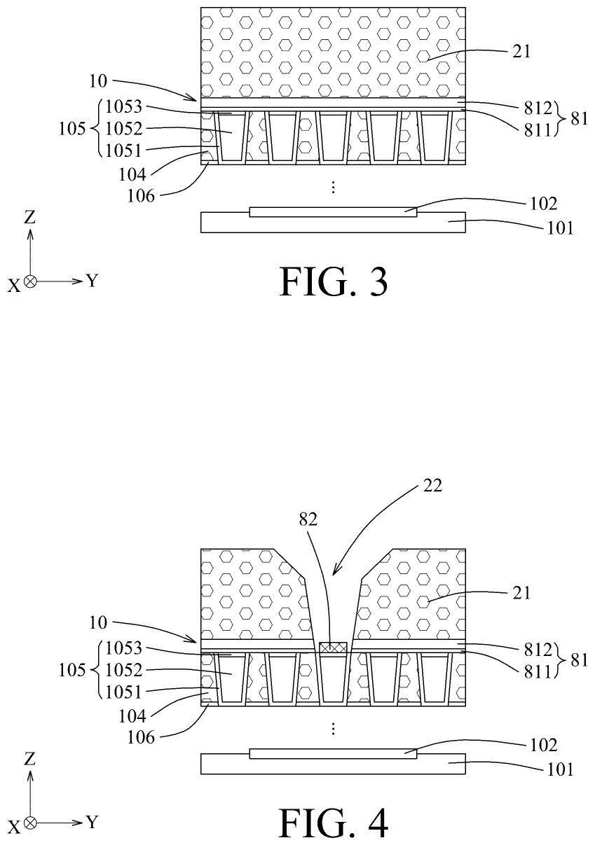

FIG. 1 is a flow diagram illustrating a method for manufacturing an interconnect structure (for example, the interconnect structures shown in FIGS. 16-18, 28-29, 39-40, and 45-50) in accordance with some embodiments. FIG. 2 is a schematic view of a plurality of levels in a semiconductor structure in accordance with some embodiments, and may not reflect an actual sectional view of the semiconductor structure. FIGS. 3 to 50 illustrate schematic views of intermediate stages of the method in accordance with some embodiments, and the steps illustrated in FIGS. 3 to 50 are also illustrated schematically in the flow diagram shown in FIG. 1. Some repeating structures are omitted in FIGS. 2 to 50 for the sake of brevity. Additional steps can be provided before, after or during the method, and some of the steps described herein may be replaced by other steps or be eliminated.

Referring to FIG. 2, in some embodiments, the semiconductor structure includes a substrate 101, a plurality of semiconductor devices 102 formed on the substrate 101, a plurality of source/drain contacts 1031, a plurality of gate contacts 1032, and a dielectric layer 1041. In some embodiments, the substrate 101 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 101 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 101 may be configured as a semiconductor-on-insulator substrate. Other suitable materials and configurations for the substrate 101 are within the contemplated scope of the present disclosure. In some embodiments, the substrate 101 may be formed with trench isolations 1011 to separate each of the semiconductor devices 102 from adjacent ones of the semiconductor devices 102. In some embodiments, the trench isolations 1011 may each be a shallow trench isolation (STI), a deep trench isolation (DTI), or other suitable structures. In some embodiments, the trench isolations 1011 may include silicon oxide, silicon nitride, silicon oxynitride, other low-k (low-dielectric constant) dielectric materials, or combinations thereof. The semiconductor devices 102 may be active devices (for example, transistors, diodes, or the like), passive devices (for example, capacitors, inductors, resistors, or the like), memory devices, decoders, amplifiers, other suitable devices, or combinations thereof. In some embodiments, the semiconductor devices 102 may be transistors. Although the semiconductor devices 102 shown in FIG. 2 are each exemplified as a planar transistor, the semiconductor devices 102 may each be a fin-type field-effect transistor (FinFET), a gate-all-around field-effect transistor (GAAFET), a forksheet field-effect transistor, a complementary field-effect transistor (CFET), other transistors with suitable configurations, or other suitable devices. In some embodiments, each of the transistors 102 may have two source/drain regions 1024 formed in the substrate 101, a channel 1025 located between the two source/drain regions 1024, a gate structure interfacing the channel 1025. The gate structure is formed in the dielectric layer 1041 in a contact-level structure L0, and has a gate dielectric layer 1021 formed over the channel 1025, a gate electrode 1022 formed over the gate dielectric layer 1021, and two spacers 1023 formed respectively at two opposite sides of the gate electrode 1022. The gate dielectric layer 1021 may include or may be made of silicon oxide, silicon nitride, silicon oxynitride, a suitable high-k material (such as hafnium oxide, zirconium oxide, zirconium aluminum oxide, hafnium aluminum oxide, hafnium silicon oxide, aluminum oxide, and so on), other suitable materials, or combinations thereof. The gate electrode 1022 may include or may be made of a metal material (e.g., tungsten (W), titanium (Ti), tantalum (Ta), aluminum (Al), or ruthenium (Ru)), metal-containing nitrides (e.g., titanium nitride (TiN), or tantalum nitride (TaN)), metal-containing silicides (e.g., nickel silicide (NiSi)), metal-containing carbides (e.g., tantalum carbide (TaC)), other suitable materials, or combinations thereof. In some embodiments, the gate electrode 1022 may include or may be made of various n-type or p-type work function metals. Examples of the n-type work function metal include Al, titanium aluminium carbide (TiAlC), TiAl, or other suitable materials. Examples of p-type work function metal include TiN, tungsten nitride (WN), tungsten carbon nitride (WCN), molybdenum nitride (MoN), or other suitable materials. The spacers 1023 may include or may be made of a nitride-based material, such as silicon nitride, silicon oxynitride, silicon carbon nitride, silicon oxycarbonnitride, other suitable materials, or combinations thereof. The semiconductor devices 102 may be electrically connected to external circuits through the source/drain contacts 1031 and the gate contacts 1032 formed in the dielectric layer 1041. In some embodiments, the dielectric layer 1041 includes or is made of a low-k dielectric material. In some embodiments, the dielectric layer 1041 includes or is made of silicon oxide, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), fluorine-doped silicon oxide, carbon-doped silicon oxide, porous silicon oxide, porous carbon-doped silicon oxide, other suitable low-k dielectric materials, or combinations thereof. Other dielectric materials suitable for the dielectric layer 1041 are within the contemplated scope of the present disclosure. In some embodiments, each of the source/drain contacts 1031 and the gate contacts 1032 includes or is made of Cu, Co, Ru, Mo, Cr, W, Mn, Rh, Ir, Ni, Pd, Ag, Au, Al, alloys thereof, graphene, other suitable conductive materials, or combinations thereof. In some embodiments, each of the source/drain contacts 1031 and the gate contacts 1032 may be formed by a single damascene process involving physical vapor deposition (hereinafter PVD), chemical vapor deposition (hereinafter CVD), atomic layer deposition (hereinafter ALD) or other suitable processes. In some embodiments, the semiconductor structure further includes one or multiple interconnect-level structures L1, L2, L3, . . . Ln (L3 to Ln are not shown). In the interconnect-level structure L1, metal lines 91 are formed in a dielectric layer 1042. In each of the interconnect-level structures L2 to Ln, metal vias 92 are formed in a dielectric layer 1043, and metal lines 91 are formed in a dielectric layer 1044. Suitable materials for the metal lines 91 and metal vias 92 are similar to those for the source/drain contacts 1031 and the gate contacts 1032, Suitable materials for the dielectric layers 1042, 1043, 1044 are similar to those for the dielectric layer 1041.

Referring to FIG. 3, a base structure 10 is shown. The base structure 10 includes the substrate 101, the semiconductor devices 102 (one of which is shown), and conductive features 105 formed in a dielectric layer 104. In some embodiments, the conductive features 105 may be the source/drain contacts 1031 and the gate contacts 1032 located in the contact-level structure L0 shown in FIG. 2. In some other embodiments, the conductive features 105 may be the metal lines 91 located in one of the interconnect-level structures L1 to Ln (only L1 and L2 are shown in FIG. 2). In certain embodiments, the conductive features 105 may be the metal vias 92 located in one of the interconnect-level structures L2 to Ln (only L2 is shown in FIG. 2). The dielectric layer 104 shown in FIG. 3 may be one of the dielectric layers 1041 to 1044 shown in FIG. 2. An etch stop layer 106 shown in FIG. 3 may be formed between two adjacent ones of the dielectric layers 1041 to 1044 shown in FIG. 2. Suitable materials for the etch stop layer 106 are similar to those for the dielectric layers 1041 to 1044, but the material of the etch stop layer 106 is different from an adjacent one of the dielectric layers 1041 to 1044. In the following descriptions, the conductive features 105 are exemplified to include metal lines. In some embodiments, each of the conductive features 105 has a thickness (measured in a Z direction) ranging from about 50 Å to about 500 Å, but other ranges of values are also within the contemplated scope of the present disclosure. In some embodiments, the conductive features 105 are spaced apart from each other in a Y direction different from (e.g., perpendicular to) the Z direction. In some embodiments, as shown in FIG. 3, each of the conductive features 105 includes a barrier 1051, a metal line 1052, and a metal cap 1053. In some embodiments, the barrier 1051 may include or be made of Ta, Ti, tantalum nitride, titanium nitride, other metal nitride, other suitable materials, or combinations thereof, and may prevent electromigration. In some embodiments, the metal line 1052 may include or be made of Cu, Co, Ru, Mo, Cr, W, Mn, Rh, Ir, Ni, Pd, Ag, Au, Al, alloys thereof, other suitable materials, or combinations thereof. In some embodiments, the metal cap 1053 may include or be made of Co, Ru, Mo, Cr, W, Mn, Rh, Ir, Ni, Pd, Ag, Au, Al, alloys thereof, other suitable materials, or combinations thereof, and may prevent electromigration. In some embodiments, the conductive features 105 are formed in the dielectric layer 104 using a single damascene process involving PVD, CVD, ALD or other suitable processes.

Referring to FIG. 3, an etch stop layer 81 is formed over the base structure 10. The etch stop layer 81 may have a single-layer structure or a multi-layer structure. In some embodiments, the etch stop layer 81 may include two etch stop sublayers 811, 812. In some embodiments, each of the etch stop sublayers 811, 812 may include or be made of aluminum nitride, aluminum oxide, silicon oxide, silicon oxycarbide, silicon oxycarbonitride, other suitable materials, or combinations thereof. In some embodiments, each of the etch stop sublayers 811, 812 may be formed using PVD, CVD, or ALD. Other materials, configurations, and/or processes suitable for forming the etch stop layer 81 are also within the contemplated scope of the present disclosure. In some other embodiments, the etch stop layer 81 may have the single-layer structure only including one of the etch stop sublayers 811, 812. Thereafter, a lower dielectric feature 21 is formed over the etch stop layer 81 and the base structure 10. Suitable materials for the lower dielectric feature 21 are similar to those for the dielectric layer 1041 described with reference to FIG. 2, and thus details thereof are omitted for the sake of brevity. The lower dielectric feature 21 may be formed by depositing a dielectric material of the lower dielectric feature 21 using a suitable deposition process such as CVD, ALD, a thermal ALD process, a spin-coating process, a spin-on process, or other suitable processes. A dielectric constant of the lower dielectric feature 21 is less than a dielectric constant of the gate dielectric layer 1021 (see FIG. 2).

Referring to FIG. 4, a patterning process is performed to form a trench 22 in the lower dielectric feature 21, to etch the etch stop layer 81, and to expose an upper surface of the metal cap 1053 of one of the conductive features 105. It is noted that, the one of the conductive features 105 will be referred to as the conductive feature 105 for the sake of brevity. In some embodiments, the patterning process may include a photolithography process and a subsequent etching process. The photolithography process may include: forming a photoresist layer over a structure to be patterned by, for example, spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In the following description, a patterning process, a photolithography process or an etching process, unless otherwise stated or defined in this disclosure, may be performed in a way similar to the above-mentioned ones. Afterwards, a base blocking film 82 is formed over the upper surface of the metal cap 1053 of the conductive feature 105. In some embodiments, the base blocking film 82 may be a self-assembled monolayer (hereinafter SAM) which can be selectively formed only on a metallic material but not on a dielectric material. As such, the base blocking film 82 may include or be made of an SAM material that only attaches to a metallic material (hereinafter SAM-on-metal material). Examples for the SAM-on-metal material may include a thiol-based compound (e.g., dodecanethiol, and/or alkanethiol), an acid-based compound (e.g., phosphonic acid, and/or octadecylphosphonic acid (hereinafter ODPA)), a bicyclic nitrogen heterocycle compound (e.g., benzotriazole), or combinations thereof. The base blocking film 82 may be formed by depositing a material of the base blocking film 82 using a suitable deposition process such as CVD, ALD, a spin-on process, a dipping process, a spray process, or other suitable processes. In some other embodiments, the base blocking film 82 may be formed by dissolving the SAM-on-metal material in a suitable solvent to form a solution, applying the solution to the trench 22, followed by removal of the solvent. Other suitable materials, processes, and/or configurations for the base blocking film 82 are within the contemplated scope of the present disclosure. Based on the material(s) of the barrier 1051 of the conductive feature 105 and the material(s) of the base blocking film 82, the base blocking film 82 may be formed to cover the barrier 1051 of the conductive feature 105 or not. In some embodiments, as shown in FIG. 4, the barrier 1051 of the conductive feature 105 is exposed from the base blocking film 82.

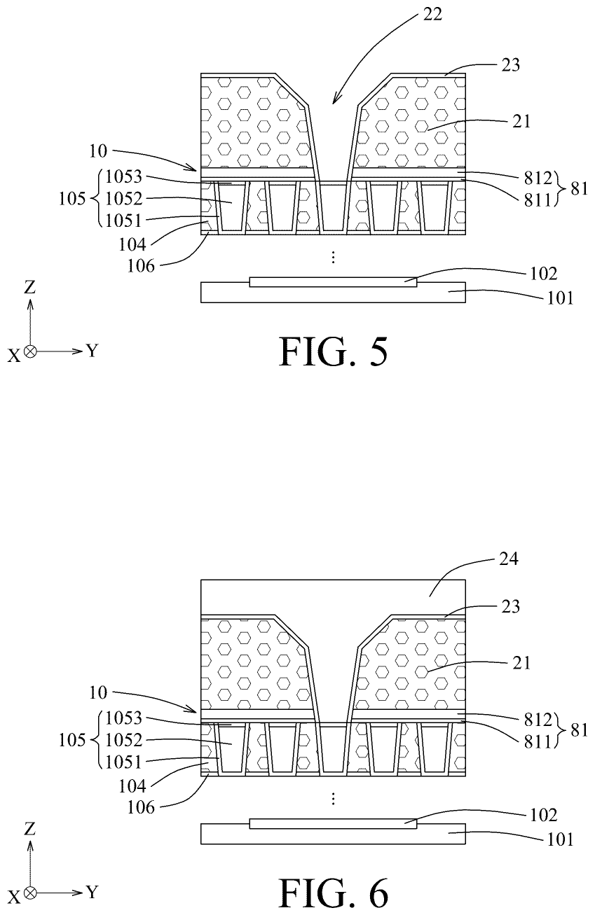

Referring to FIG. 5, a barrier layer 23 is formed over an upper surface and an inner surface of the lower dielectric feature 21, while the base blocking film 82 (see FIG. 4) is exposed from the barrier layer 23. In this case, the base blocking film 82 serves as an inhibitor for preventing the barrier layer 23 to be formed thereon. The barrier layer 23 may be formed using, for example, CVD, ALD or other suitable processes. Suitable materials for forming the barrier layer 23 are similar to those for forming the barrier 1051 of the conductive feature 105, and thus details thereof are omitted for the sake of brevity. The material of the barrier layer 23 may be the same as or different from the material of the barrier 1051. After the barrier layer 23 is formed, the base blocking film 82 (see FIG. 4) is removed by a removing process. The removing process may be performed using a suitable etching process, such as dry etching, wet etching, an ashing process, other suitable processes, or combinations thereof, so as to obtain a structure as illustrated in FIG. 5. For example, the removing process may be a gas soak process involving N₂, H₂, NH₃, CO₂, O₂, air, or combinations thereof, a plasma treatment performed in environments of N₂, H₂, NH₃, CO₂, O₂, air, or combinations thereof, or an acid or solution clean/etch process performed at temperatures from a room temperature to higher temperatures.

Referring to FIG. 6, a lower conductive feature 24 is formed over the barrier layer 23 to fill the trench 22 (see FIG. 5) and to cover the lower dielectric feature 21. The lower conductive feature 24 is formed using a deposition process, for example, PVD, CVD, ALD or other suitable deposition processes. Suitable materials for forming the lower conductive feature 24 are similar to those for forming the metal line 1052 of the conductive feature 105, and thus details thereof are omitted for the sake of brevity. The material of the lower conductive feature 24 may be the same as or different from the material of the metal line 1052. In some embodiments, an electrical conductivity of the barrier layer 23 is less than an electrical conductivity of the lower conductive feature 24.

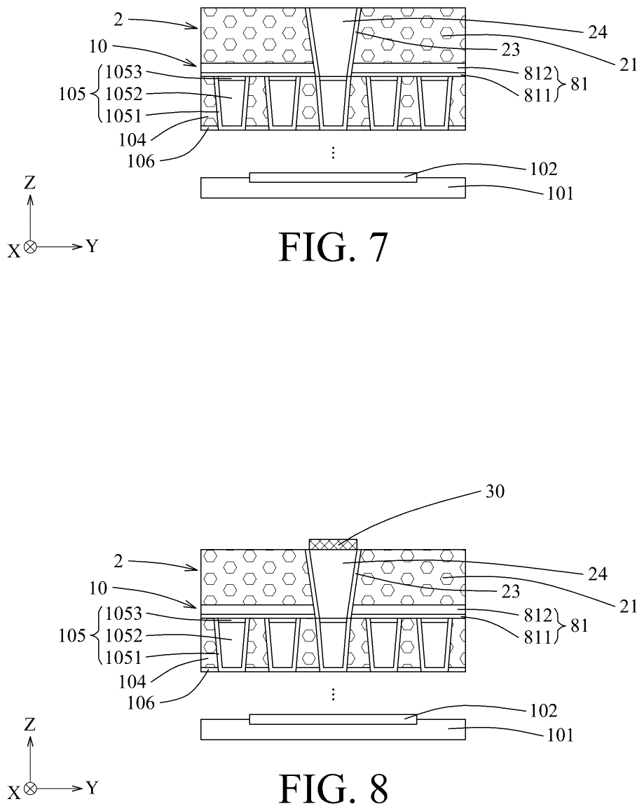

Referring to FIG. 7, a planarization process (e.g., a chemical mechanical polishing process (CMP)) is performed on the lower conductive feature 24. After the planarization process, a lower interconnect layer 2 is formed and includes the lower dielectric feature 21, the barrier layer 23 and the lower conductive feature 24. At this time, the lower dielectric feature 21 is exposed from the barrier layer 23 and the lower conductive feature 24, the barrier layer 23 is exposed from the lower conductive feature 24, and the lower interconnect layer 2 has a planarized upper surface. In some embodiments, the lower conductive feature 24 is exemplified as a metal via. In some other embodiments, when the conductive features 105 are metal vias, the lower conductive feature 24 may be a metal line.

Referring to FIG. 8, a first blocking film 30 is formed over the lower conductive feature 24, while the lower dielectric feature 21 is exposed from the first blocking film 30. The first blocking film 30 is selectively formed only on a metallic material but not on a dielectric material, and thus suitable materials and processes for forming the first blocking film 30 are similar to those for forming the base blocking film 82 (see FIG. 4), and thus details thereof are omitted for the sake of brevity. The material of the first blocking film 30 may be the same as or different from the material of the base blocking film 82 (see FIG. 4). Based on the material(s) of the barrier layer 23 and the material(s) of the first blocking film 30, the first blocking film 30 may be formed to cover the barrier layer 23 or not. In some embodiments, as shown in FIG. 8, the barrier layer 23 is exposed from the first blocking film 30.

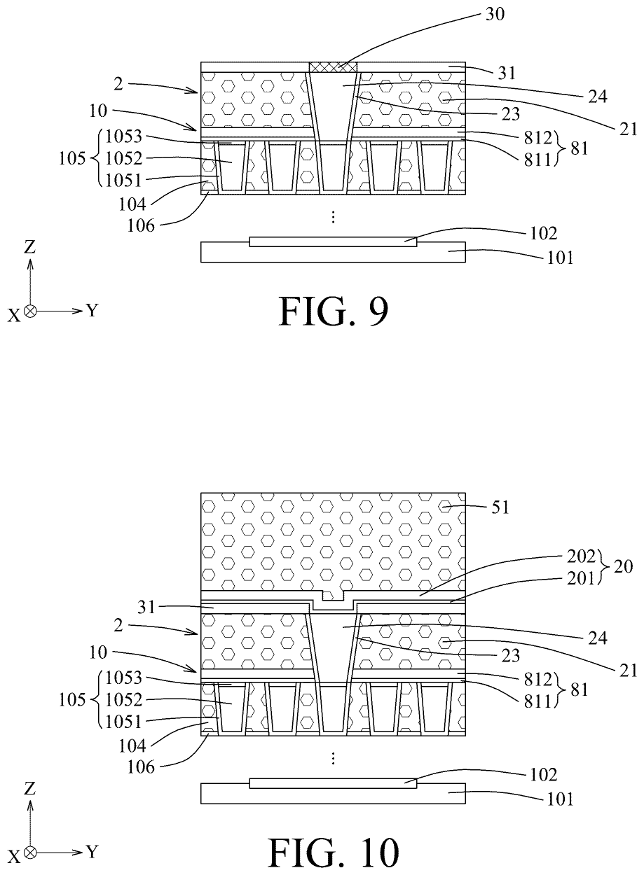

Referring to FIG. 9, a dielectric layer 31 is formed over (i.e., formed on) the lower dielectric feature 21, while the first blocking film 30 is exposed from the dielectric layer 31. In this case, the first blocking film 30 serves as an inhibitor for preventing the dielectric layer 31 to be formed thereon. In some embodiments, the dielectric layer 31 may include or be made of a dielectric material that includes silicon, oxygen, carbon, nitrogen, aluminum, hafnium, zirconium, titanium, yttrium, or combinations thereof, and that is different from the material of the lower dielectric feature 21. In some other embodiments, the dielectric layer 31 may include or be made of aluminum oxide (AlO), aluminum oxycarbide (AlOC), aluminum oxynitride (AlON), aluminum oxycarbonitride (AlOCN), aluminum silicate (AlSiO), silicon aluminum oxynitride (AlSiON), aluminum silicon oxycarbonitride (AlSiOCN, e.g., aluminum-containing silicon oxycarbonitride or silicon-containing aluminum oxycarbonitride), hafnium nitride (HfN), hafnium oxynitride (HfON), hafnium silicate (HfSiO), hafnium silicon oxynitride (HfSiON), hafnium silicon oxycarbide (HfSiOC), hafnium silicon oxycarbonitride (HfSiOCN, e.g., hafnium-containing silicon oxycarbonitrde or silicon-containing hafnium oxycarbonitrde), zirconium silicate (ZrSiO), zirconium silicon oxycarbide (ZrSiOC, e.g., zirconium-containing silicon oxycarbide or silicon-containing zirconium oxycarbide), zirconium silicon oxycarbonitride (ZrSiOCN, e.g., zirconium-containing silicon oxycarbonitrde or silicon-containing zirconium oxycarbonitrde), titanium oxynitride (TiON), titanium silicate (TiSiO), titanium silicon oxycarbide (TiSiOC), titanium oxycarbide (TiOC), yttrium silicate (YSiO), yttrium silicon oxycarbide (YSiOC, e.g., yttrium-containing silicon oxycarbide or silicon-containing yttrium oxycarbide), yttrium silicon oxycarbonitride (YSiOCN, e.g., yttrium-containing silicon oxycarbonitrde or silicon-containing yttrium oxycarbonitrde), or combinations thereof. In some embodiments, the dielectric layer 31 may be formed by CVD, ALD, molecular layer deposition (hereinafter MLD), a spin-on process, a catalyzed growth process, other suitable processes, or combinations thereof. In some embodiments, the dielectric layer 31 has a thickness (measured in the Z direction) ranging from about 5 Å to about 100 Å, but other ranges of values are also within the contemplated scope of the present disclosure. In some embodiments, the dielectric 31 has a dielectric constant ranging from about 4 to about 20 (e.g., ranging from about 4 to about 8, ranging from about 6 to about 10, ranging from about 8 to about 12, ranging from about 10 to about 14, ranging from about 12 to about 16, ranging from about 14 to about 18, or ranging from about 16 to about 20). The amount and/or the species of the metal element(s) in the dielectric layer 31 may affect the dielectric constant of the dielectric layer 31.

Referring to FIG. 10, the first blocking film 30 (see FIG. 9) is removed by a removing process. Suitable processes for removing the first blocking film 30 (see FIG. 9) are similar to those for removing the base blocking film 82 (see FIG. 4), and thus details thereof are omitted for the sake of brevity. At this time, the lower conductive feature 24 is exposed from the dielectric layer 31. Thereafter, an etch stop layer 20 is formed over the lower interconnect layer 2 to cover the dielectric layer 31 and the lower dielectric feature 24. The etch stop layer 20 may have a single-layer structure or multi-layer structure. In some embodiments, the etch stop layer 20 may include two etch stop sublayers 201, 202. Suitable materials and processes for forming each of the etch stop sublayers 201, 202 are similar to those for forming each of the etch stop sublayers 811, 812, and thus details thereof are omitted for the sake of brevity. The material of the etch stop layer 20 may be the same as or different from the material of the etch stop layer 81. In some embodiments, the material of the etch stop layer 20 is different from each of the material of the dielectric layer 31 and the material of the lower dielectric feature 21. In some other embodiments, the etch stop layer 20 may have the single-layer structure only including one of the etch stop sublayers 201, 202. Then, an upper dielectric feature 51 is formed over the etch stop layer 20 (i.e., the upper dielectric feature 51 is formed over the lower interconnect layer 2 opposite to the base structure 10 to cover the dielectric layer 31). At this time, the dielectric layer 31 is disposed between the lower interconnect layer 2 and the upper dielectric feature 51. Suitable materials and processes for forming the upper dielectric feature 51 are similar to those for forming the lower dielectric feature 21, and thus details thereof are omitted for the sake of brevity. The material of the upper dielectric feature 51 may be the same as or different from the material of the lower dielectric feature 21. In some embodiments, the material of the upper dielectric feature 51 is different from the material of the dielectric layer 31. In some embodiments, the upper dielectric feature 51 is thicker than the lower dielectric feature 21. A dielectric constant of the upper dielectric feature 51 is less than a dielectric constant of the gate dielectric layer 1021 (see FIG. 2).

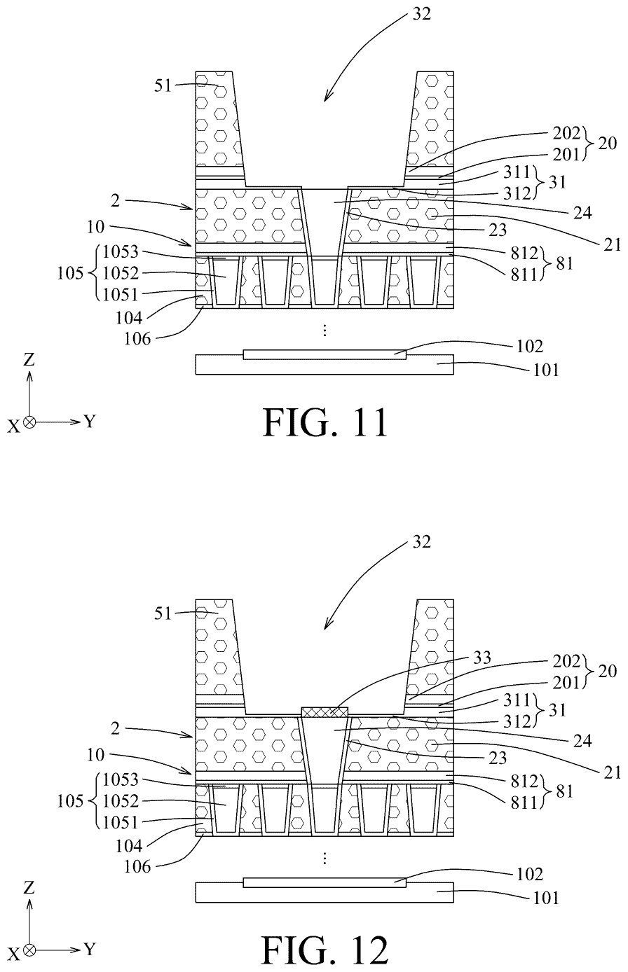

Referring to FIG. 11, a patterning process is performed to form a trench 32 in the upper dielectric feature 51, to etch the etch stop layer 20, to etch the dielectric layer 31, and to expose an upper surface of the lower conductive feature 24. Suitable processes for forming the trench 32 are similar to those for forming the trench 22 (see FIG. 4), and thus details thereof are omitted for the sake of brevity. In the patterning process, a section of the etch stop layer 20 is entirely removed and a section of the dielectric layer 31 previously under the section of the etch stop layer 20 is partially removed such that the section of the dielectric layer 31 remaining is exposed to the trench 32. To be specific, the dielectric layer 31 has a non-etched portion 311 covered by the upper dielectric feature 51 (i.e., the non-etched portion 311 is disposed between the upper dielectric feature 51 and the lower dielectric feature 21), and an etched portion 312 exposed to the trench 32 (i.e., the etched portion 312 is the section of the dielectric layer 31 remaining). In some embodiments, the lower dielectric feature 21 is covered by the etched portion 312. A thickness of the etched portion 312 is less than a thickness of the non-etched portion 311. In some embodiments, the lower dielectric feature 21 is not exposed to the trench 32. In some other embodiments, the lower dielectric feature 21 is exposed to the trench 32 (i.e., the dielectric layer 31 only has the non-etched portion 311). It is noted that with the provision of the dielectric layer 31 for protecting the lower dielectric feature 21, an upper surface of the etched portion 312 or an upper surface of the exposed lower dielectric feature 21 may be kept flat after the patterning process. In other words, the lower dielectric feature 21 is less likely to be undesirably damaged in the patterning process. In some embodiments, a width of the trench 32 is greater than a width of the lower conductive feature 24, and a bottommost point in the trench 32 is at a level not lower than a level of the upper surface of the lower conductive feature 24.

Referring to FIG. 12, a second blocking film 33 is formed over the upper surface of the lower conductive feature 24, while an inner surface of the trench 32, except the upper surface of the lower conductive feature 24, is exposed from the second blocking film 33. The second blocking film 33 is selectively formed only on a metallic material but not on a dielectric material, and thus suitable materials and processes for forming the second blocking film 33 are similar to those for forming the first blocking film 30 (see FIG. 9), and thus details thereof are omitted for the sake of brevity. The material of the second blocking film 33 may be the same as or different from the material of the first blocking film 30 (see FIG. 9).

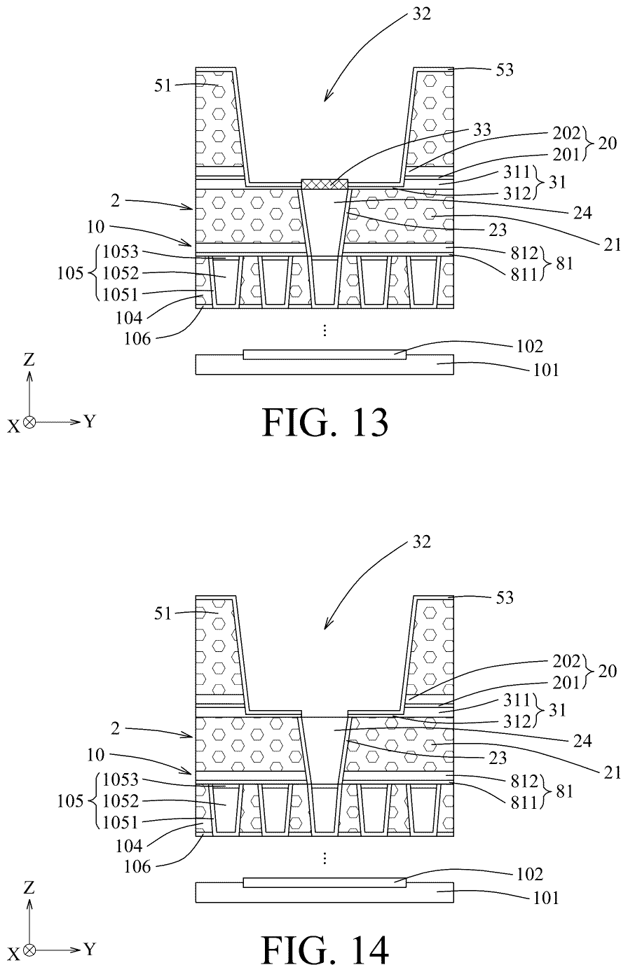

Referring to FIG. 13, a barrier layer 53 is formed over an upper surface and an inner surface of the upper dielectric feature 51, while the second blocking film 33 is exposed from the barrier layer 53. In this case, the second blocking film 33 serves as an inhibitor for preventing the barrier layer 53 to be formed thereon. Suitable materials and processes for forming the barrier layer 53 are similar to those for forming the barrier layer 23, and thus details thereof are omitted for the sake of brevity. The material of the barrier layer 53 may be the same as or different from the material of the barrier layer 23.

Referring to FIG. 14, after the barrier layer 53 is formed, the second blocking film 33 (see FIG. 13) is removed by a removing process. Suitable processes for removing the second blocking film 33 (see FIG. 13) are similar to those for removing the first blocking film 30 (see FIG. 9), and thus details thereof are omitted for the sake of brevity. At this time, the lower conductive feature 24 is exposed from the barrier layer 53.

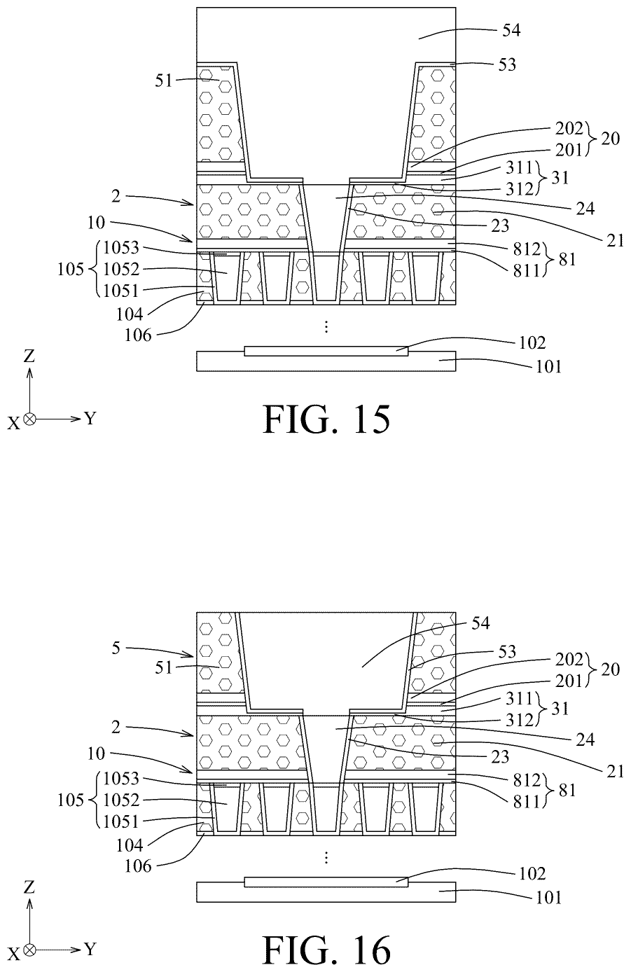

Referring to FIG. 15, an upper conductive feature 54 is formed over the barrier layer 53 to fill the trench 32 (see FIG. 14) and to cover the upper dielectric feature 51. In addition, the etched portion 312 of the dielectric layer 31 is disposed between the upper conductive feature 54 and the lower dielectric feature 21. Suitable materials and processes for forming the upper conductive feature 54 are similar to those for forming the lower conductive feature 24, and thus details thereof are omitted for the sake of brevity. The material of the upper conductive feature 54 may be the same as or different from the material of the lower conductive feature 24. In some embodiments, an electrical conductivity of the barrier layer 53 is less than an electrical conductivity of the upper conductive feature 54.

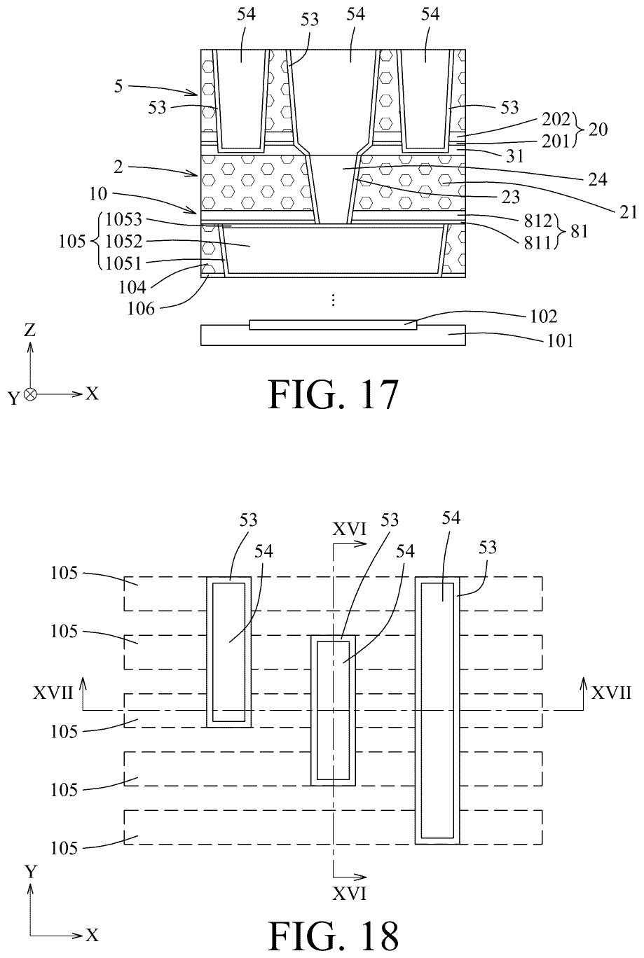

Referring to FIG. 16, a planarization process (e.g., CMP) is performed on the upper conductive feature 54. After the planarization process, an upper interconnect layer 5 is formed and includes the upper dielectric feature 51, the barrier layer 53 and the upper conductive feature 54. In addition, the upper dielectric feature 51 is still thicker than the lower dielectric feature 21. At this time, the upper dielectric feature 51 is exposed from the barrier layer 53 and the upper conductive feature 54, the barrier layer 53 is exposed from the upper conductive feature 54, and the upper interconnect layer 5 has a planarized upper surface. In some embodiments, the upper conductive feature 54 is exemplified as a metal line. In some other embodiments, when the lower conductive feature 24 is a metal line, the upper conductive feature 54 may be a metal via. It is noted that, the interconnect structure may include a plurality of upper conductive features 54 and a plurality of barrier layers 53. The upper conductive features 54 are spaced apart from each other in an X direction different from (e.g., perpendicular to) the Y and Z directions. Each of the barrier layers 53 is formed around a respective one of the upper conductive features 54. FIG. 18 is a schematic layout diagram illustrating a possible positional relationship among the upper conductive features 54, the barrier layers 53 and the conductive features 105 in accordance with some embodiments, with other elements omitted. FIG. 16 is a schematic sectional view (a Y-cut view) taken along line XVI-XVI of FIG. 18 to illustrate one of the upper conductive features 54 in accordance with some embodiments. FIG. 17 is a schematic sectional view (an X-cut view) taken along line XVII-XVII of FIG. 18 to illustrate the upper conductive features 54 in accordance with some embodiments.

In some embodiments, some steps in the method may be modified, replaced, or eliminated without departure from the spirit and scope of the present disclosure. In some alternative embodiments, the interconnecting structure may further include additional features, and/or some features present in the interconnect structure may be modified, replaced, or eliminated without departure from the spirit and scope of the present disclosure. The method illustrated by FIG. 1 may be applied for forming another interconnect structure in which the materials used therein and/or the aspect ratio and/or the pitch of the conductive lines/vias are different from those illustrated in step S01 to S05. The method illustrated by FIG. 1 may further be applied for a semiconductor manufacturing process that uses 1.4 nanometer technology, or technology involving a dimension greater/smaller than 1.4 nanometer. Furthermore, other techniques suitable for forming the interconnect structure that serves as the interconnect-level structure L1 and/or the interconnect-level structure L2, and/or the another interconnect-level structure Ln (not shown) may be integrated into the method of this disclosure.

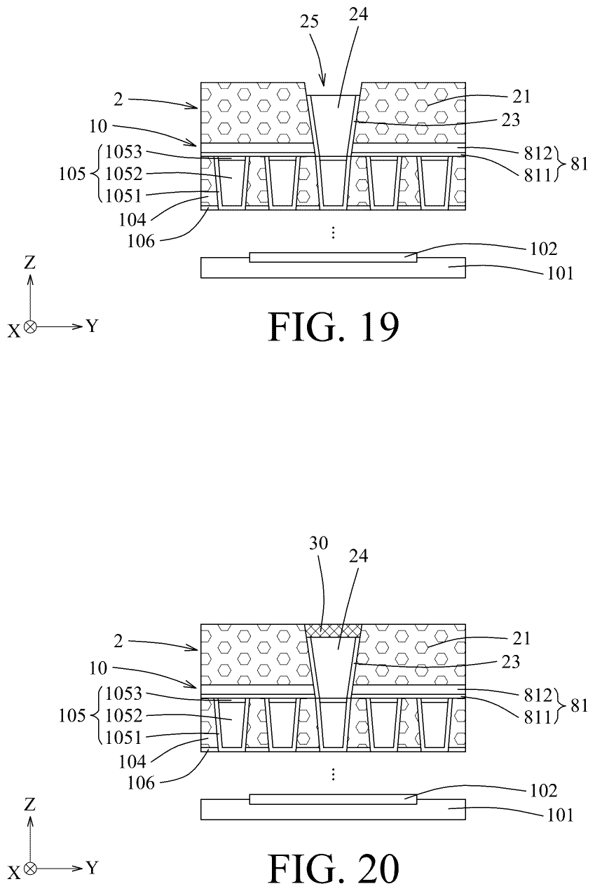

FIGS. 19 to 29 are each a Y-cut or an X-cut view subsequent to FIG. 7, and illustrate possible intermediate stages of the method depicted in FIG. 1 in accordance with some embodiments.

Referring to FIG. 19, after the lower interconnect layer 2 is formed (see also FIG. 7), a via recessing process is performed on the lower conductive feature 24 such that an upper portion of the lower conductive feature 24 and an upper portion of the barrier layer 23 are removed and such that a recess 25 is formed. In some embodiments, the via recessing process may be an etching process such as Cu etching control process (e.g., a dry plasma etching process or a wet acid etching process), or other suitable processes. After the recess is formed, an upper surface of the lower dielectric feature 21 is higher than an upper surface of the lower conductive feature 24 and an upper surface of the barrier layer 23 in the Z direction.

Referring to FIG. 20, the first blocking film 30 is formed over the lower conductive feature 24, and the lower dielectric feature 21 is exposed from the first blocking film 30. In some embodiments, based on the material(s) of the barrier layer 23 and the material(s) of the first blocking film 30, the first blocking film 30 may be formed to cover the barrier layer 23 or not. In some embodiments, as shown in FIG. 20, the first blocking film 30 is formed to cover the barrier layer 23. Suitable materials and processes for forming the first blocking film 30 are similar to those for forming the first blocking film 30 described with reference to FIG. 8, and thus the details thereof are omitted for the sake of brevity.

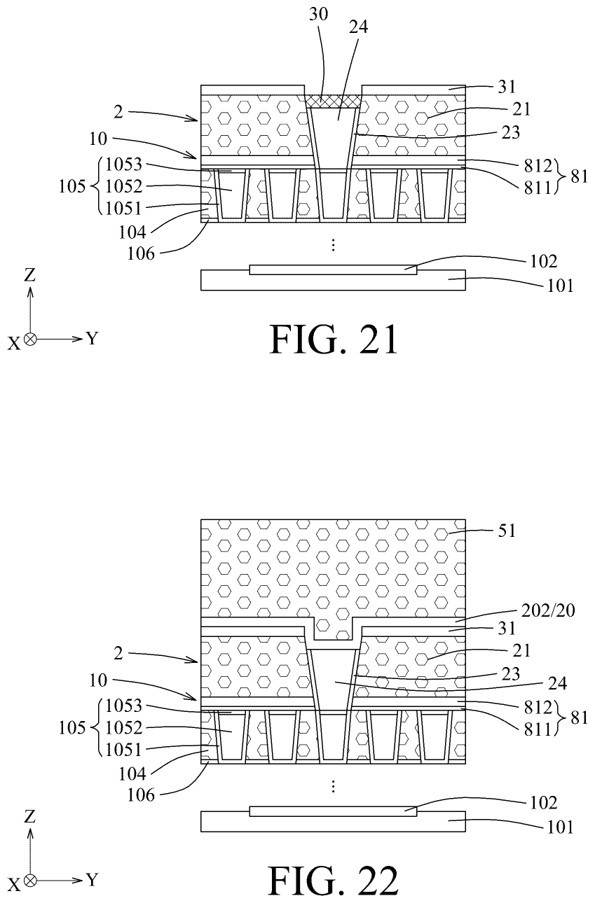

Referring to FIG. 21, the dielectric layer 31 is formed over (i.e., formed on) the lower dielectric feature 21, while the first blocking film 30 is exposed from the dielectric layer 31. In this case, the first blocking film 30 serves as an inhibitor for preventing the dielectric layer 31 to be formed thereon. Suitable materials and processes for forming the dielectric layer 31 are similar to those for forming the dielectric layer 31 described with reference to FIG. 9, and thus the details thereof are omitted for the sake of brevity.

Referring to FIG. 22, the first blocking film 30 (see FIG. 21) is removed by a removing process, and then the etch stop layer 20 and the upper dielectric feature 51 are formed in a way similar to those described with reference to FIG. 10. As such, the details are omitted for the sake of brevity. In some embodiments, when the first blocking film 30 (see FIG. 21) is removed, the lower conductive feature 24 and the barrier layer 23 are exposed from the dielectric layer 31. In some embodiments, the etch stop layer 20 is a single-layer structure 202 made of a material similar to the etch stop sublayer 202 described with reference to FIG. 10.

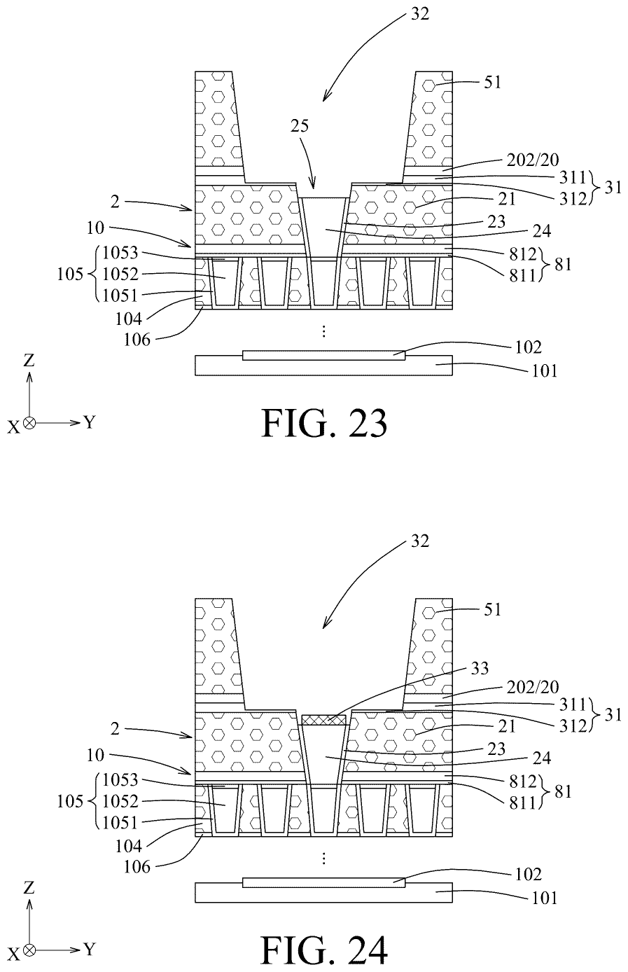

Referring to FIG. 23, a patterning process is performed to form the trench 32 in the upper dielectric feature 51, to etch the etch stop layer 20, to etch the dielectric layer 31, and to expose the upper surface of the lower conductive feature 24. Suitable processes for forming the trench 32 are similar to those for forming the trench 32 described with reference to FIG. 11, and thus details thereof are omitted for the sake of brevity. In some embodiments, the dielectric layer 31 shown in FIG. 23 has the non-etched portion 311 and the etched portion 312 as described with reference to FIG. 11, and thus details thereof are omitted for the sake of brevity. In some embodiments, an upper surface of the lower dielectric feature 21 is not exposed to the trench 32, and an inner surface of the lower dielectric feature 21 is exposed to the trench 32 through the recess 25 above the lower conductive feature 24. In some other embodiments, the lower dielectric feature 21 is exposed to the trench 32 (i.e., the dielectric layer 31 only has the non-etched portion 311). In some embodiments, with the provision of the dielectric layer 31, the bottommost point in the trench 32 is at a level lower than a level of the dielectric layer 31 but not lower than the level of the upper surface of the lower conductive feature 24.

Referring to FIG. 24, the second blocking film 33 is formed over the upper surface of the lower conductive feature 24, while the inner surface of the trench 32, except the upper surface of the lower conductive feature 24, is exposed from the second blocking film 33. Suitable materials and processes for forming the second blocking film 33 are similar to those for forming the second blocking film 33 described with reference to FIG. 12, and thus details thereof are omitted for the sake of brevity. Based on the material(s) of the barrier layer 23 and the material(s) of the second blocking film 33, the second blocking film 33 may be formed to cover the barrier layer 23 or not. In some embodiments, as shown in FIG. 24, the barrier layer 23 is exposed from the second blocking film 33.

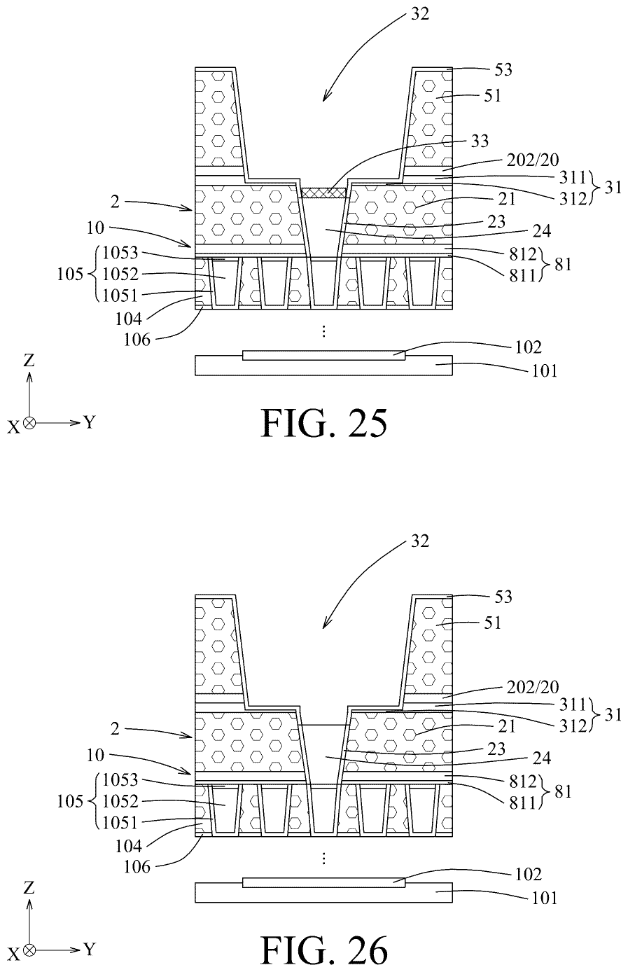

Referring to FIG. 25, the barrier layer 53 is formed over the upper surface and the inner surface of the upper dielectric feature 51, while the second blocking film 33 is exposed from the barrier layer 53. In this case, the second blocking film 33 serves as an inhibitor for preventing the barrier layer 53 to be formed thereon. Suitable materials and processes for forming the barrier layer 53 are similar to those for forming the barrier layer 53 described with reference to FIG. 13, and thus details thereof are omitted for the sake of brevity.

Referring to FIG. 26, after the barrier layer 53 is formed, the second blocking film 33 (see FIG. 25) is removed by a removing process. Suitable processes for removing the second blocking film 33 (see FIG. 25) are similar to those for removing the second blocking film 33 described with reference to FIG. 14, and thus details thereof are omitted for the sake of brevity. At this time, the lower conductive feature 24 is exposed from the barrier layer 53.

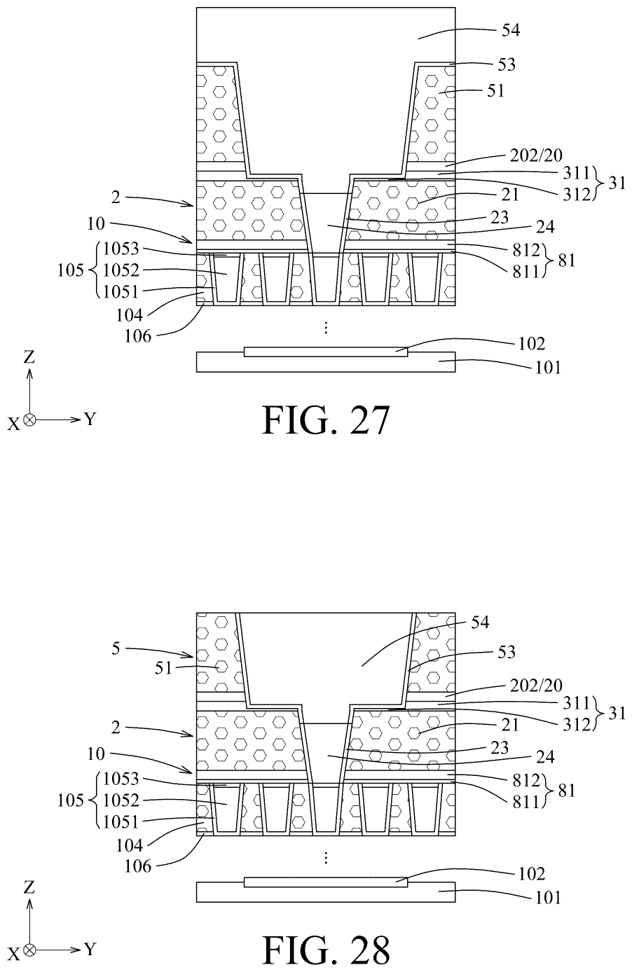

Referring to FIG. 27, the upper conductive feature 54 is formed over the barrier layer 53 to fill the trench 32 (see FIG. 26) and to cover the upper dielectric feature 51. In addition, the etched portion 312 of the dielectric layer 31 is disposed between the upper conductive feature 54 and the lower dielectric feature 21. Suitable materials and processes for forming the upper conductive feature 54 are similar to those for forming the upper conductive feature 54 described with reference to FIG. 15, and thus details thereof are omitted for the sake of brevity.

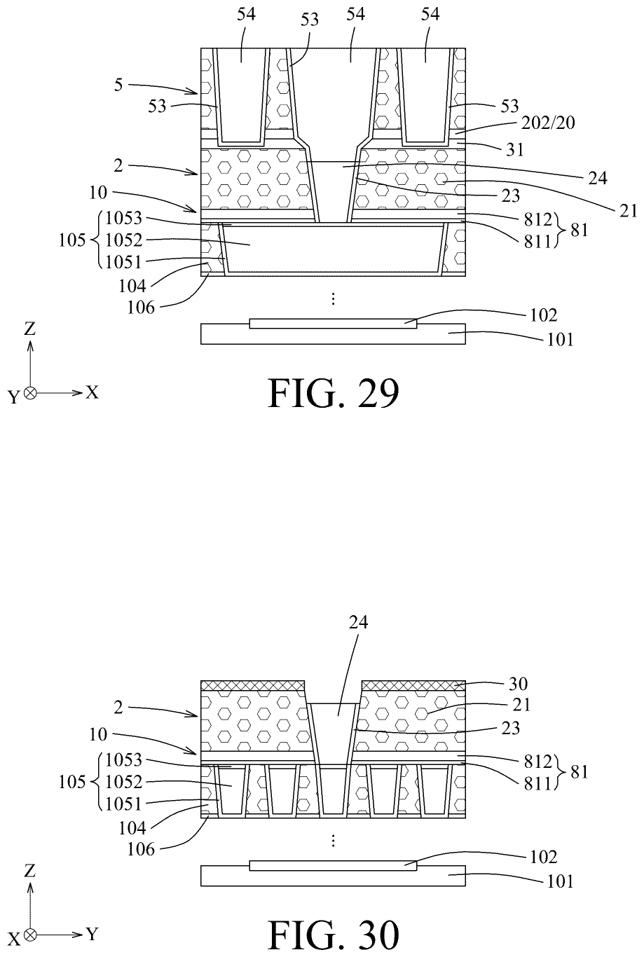

Referring to FIG. 28, a planarization process (e.g., CMP) is performed on the upper conductive feature 54. After the planarization process, the upper interconnect layer 5 is formed, and includes the upper dielectric feature 51, the barrier layer 53 and the upper conductive feature 54. In addition, the upper dielectric feature 51 is still thicker than the lower dielectric feature 21. At this time, the upper dielectric feature 51 is exposed from the barrier layer 53 and the upper conductive feature 54, the barrier layer 53 is exposed from the upper conductive feature 54, and the upper interconnect layer 5 has the planarized upper surface. It is noted that, the interconnect structure may include a plurality of upper conductive features 54 and a plurality of barrier layers 53. FIG. 28 is a s chematic sectional view (a Y-cut view) illustrating one of the upper conductive features 54 in accordance with some embodiments. FIG. 29 is a schematic sectional view (an X-cut view) illustrating the upper conductive features 54 in accordance with some embodiments.

FIGS. 30 to 40 are each a Y-cut or an X-cut view subsequent to FIG. 19, and illustrate possible intermediate stages of the method depicted in FIG. 1 in accordance with some embodiments.

Referring to FIG. 30, a first blocking film 30 is formed over the lower dielectric feature 21, while the lower conductive feature 24 is exposed from the first blocking film 30. The first blocking film 30 shown in FIG. 30 is made of a material different from the SAM-on-metal material of the base blocking film 82 shown in FIG. 4 and the SAM-on-metal material of the first blocking film 30 shown in FIG. 8 or 20. The first blocking film 30 shown in FIG. 30 is selectively formed only on a dielectric material but not on a metallic material. In some embodiments, the first blocking film 30 shown in FIG. 30 may include or be made of an SAM material that only attaches to a dielectric material (hereinafter SAM-on-dielectric material). Examples for the SAM-on-dielectric material may include a silane-based compound. In some embodiments, the SAM-on-dielectric material may include or be made of octadecyltrichlorosilane (ODTS), octadecyltrimethoxysilane (OTMS), (3-aminopropyl)triethoxysilane (APTES), butyltriethoxysilane, cyclohexyltrimethoxysilane, cyclopentyltrimethoxysilane, dodecyltriethoxysilane, dodecyltrimethoxysilane, decyltriethoxysilane, dimethoxy(methyl)-n-octylsilane, triethoxyethylsilane, ethyltrimethoxysilane, hexyltrimethoxysilane, hexyltriethoxysilane, hexadecyltrimethoxysilane, hexadecyltriethoxysilane, triethoxymethylsilane, or combinations thereof. The first blocking film 30 may be formed by depositing a material of the first blocking film 30 using a suitable deposition process such as CVD, ALD, a spin-on process, a dipping process, a spray process, or other suitable processes. In some other embodiments, the first blocking film 30 shown in FIG. 30 may be formed by the SAM-on-dielectric material in a suitable solvent to form a solution, applying the solution to the lower dielectric feature 21, followed by removal of the solvent. Other suitable materials, processes, and/or configurations for the first blocking film 30 shown in FIG. 30 are within the contemplated scope of the present disclosure.

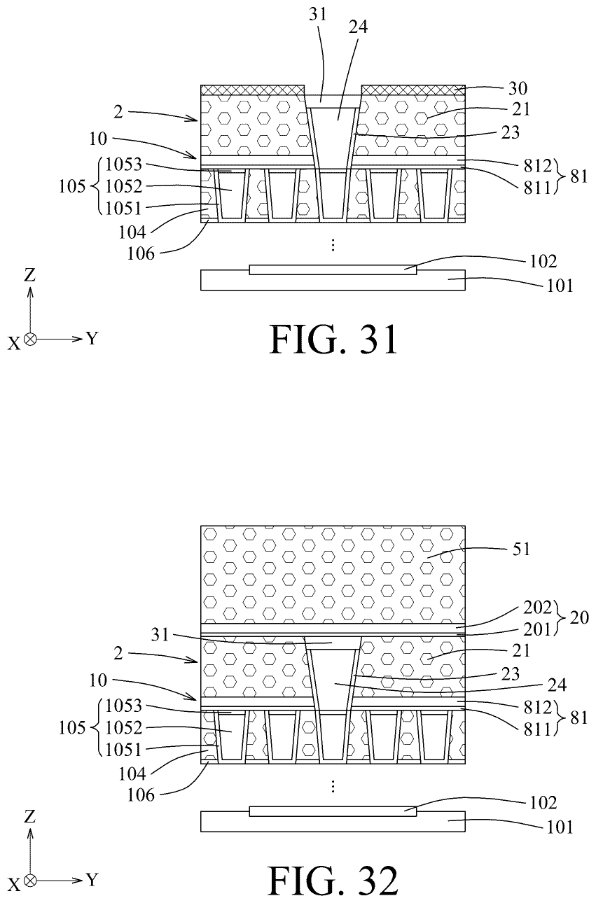

Referring to FIG. 31, a dielectric layer 31 is formed over (i.e., formed on) the lower conductive feature 24, while the first blocking film 30 is exposed from the dielectric layer 31. In this case, the first blocking film 30 serves as an inhibitor for preventing the dielectric layer 31 to be formed thereon. Suitable materials and processes for forming the dielectric layer 31 are similar to those for forming the dielectric layer 31 described with reference to FIG. 9, and thus the details thereof are omitted for the sake of brevity. It is noted that different from the dielectric layer 31 shown in FIG. 9, since the first blocking film 30 in FIG. 31 is formed on the lower dielectric feature 21, the dielectric layer 31 shown in FIG. 31 is formed on the lower conductive feature 24.

Referring to FIG. 32, the first blocking film 30 (see FIG. 31) is removed by a removing process. Suitable processes for removing the first blocking film 30 (see FIG. 31) are similar to those for removing the first blocking film 30 described with reference to FIG. 10, and thus details thereof are omitted for the sake of brevity. At this time, the lower dielectric feature 21 is exposed from the dielectric layer 31. Thereafter, the etch stop layer 20 and the upper dielectric feature 51 are formed in a way similar to those described with reference to FIG. 10, and thus details thereof are omitted for the sake of brevity. In some embodiments, an upper surface of the dielectric layer 31 and the upper surface of the lower dielectric feature 21 are flush with each other, and the etch stop layer 20 may have a flat upper surface. At this time, the dielectric layer 31 is disposed between the lower conductive feature 24 and the upper dielectric feature 51. In some embodiments, the upper dielectric feature 51 is thicker than the lower dielectric feature 21.

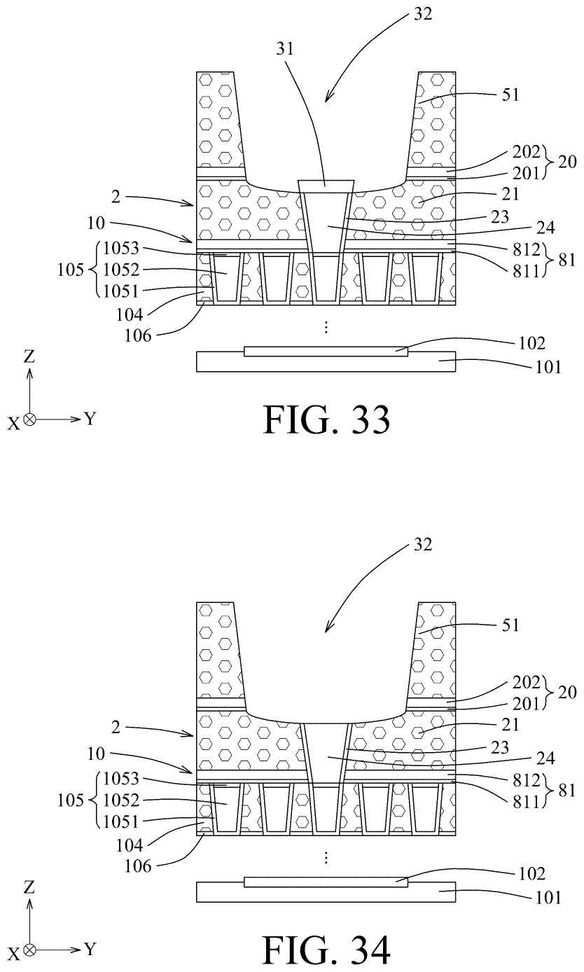

Referring to FIG. 33, a patterning process is performed to form the trench 32 in the upper dielectric feature 51, to etch the etch stop layer 20, to etch the lower dielectric feature 21, and to expose the dielectric layer 31. Suitable processes for forming the trench 32 are similar to those for forming the trench 32 described with reference to FIG. 11, and thus details thereof are omitted for the sake of brevity. In some embodiments, the dielectric layer 31 and a portion of the lower dielectric feature 21 are exposed to the trench 32, and the lower conductive feature 24 is still covered by the dielectric layer 31. In some embodiments, the width of the trench 32 is greater than the width of the lower conductive feature 24. In some embodiments, with the provision of the dielectric layer 31, the patterning process may stop when the dielectric layer 31 is exposed. Therefore, although the bottommost point in the trench 32 is at a level lower than a level of an upper surface of the dielectric layer 31, it is not lower than a level of the upper surface of the lower conductive feature 24.

Referring to FIG. 34, in the patterning process, the dielectric layer 31 (see FIG. 33) is further removed by a removing process to expose the upper surface of the lower conductive feature 24. The removing process may be performed using a suitable etching process, such as wet etching, other suitable processes, or combinations thereof, so as to obtain a structure as illustrated in FIG. 34.

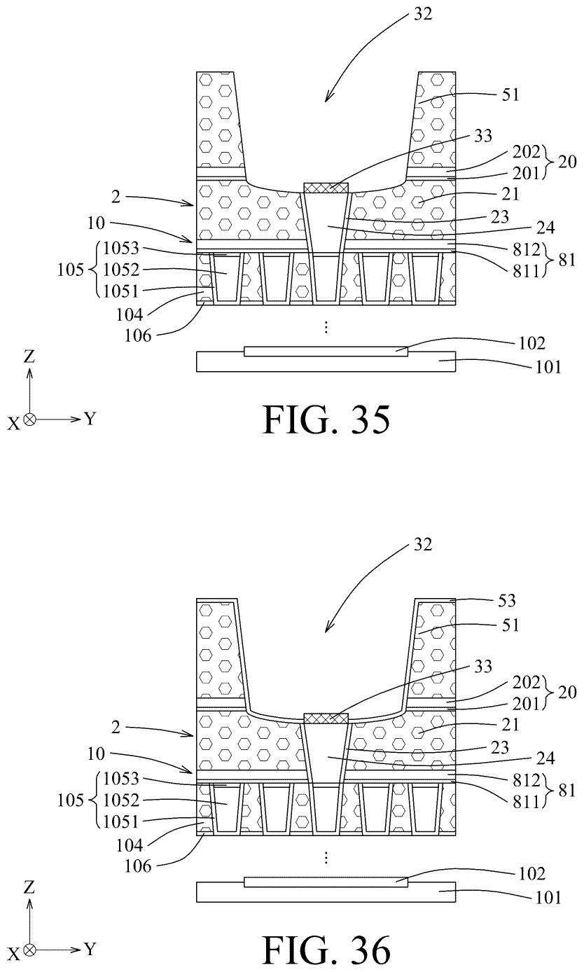

Referring to FIG. 35, the second blocking film 33 is formed over the upper surface of the lower conductive feature 24, while the inner surface of the trench 32, except the upper surface of the lower conductive feature 24, is exposed from the second blocking film 33. Suitable materials and processes for forming the second blocking film 33 are similar to those for forming the second blocking film 33 described with reference to FIG. 12, and thus details thereof are omitted for the sake of brevity. Based on the material(s) of the barrier layer 23 and the material(s) of the second blocking film 33, the second blocking film 33 may be formed to cover the barrier layer 23 or not. In some embodiments, as shown in FIG. 35, the barrier layer 23 is exposed from the second blocking film 33.

Referring to FIG. 36, the barrier layer 53 is formed over the upper surface and the inner surface of the upper dielectric feature 51 and an inner surface of the lower dielectric feature 21, while the second blocking film 33 is exposed from the barrier layer 53. In this case, the second blocking film 33 serves as an inhibitor for preventing the barrier layer 53 to be formed thereon. Suitable materials and processes for forming the barrier layer 53 are similar to those for forming the barrier layer 53 described with reference to FIG. 13, and thus details thereof are omitted for the sake of brevity.

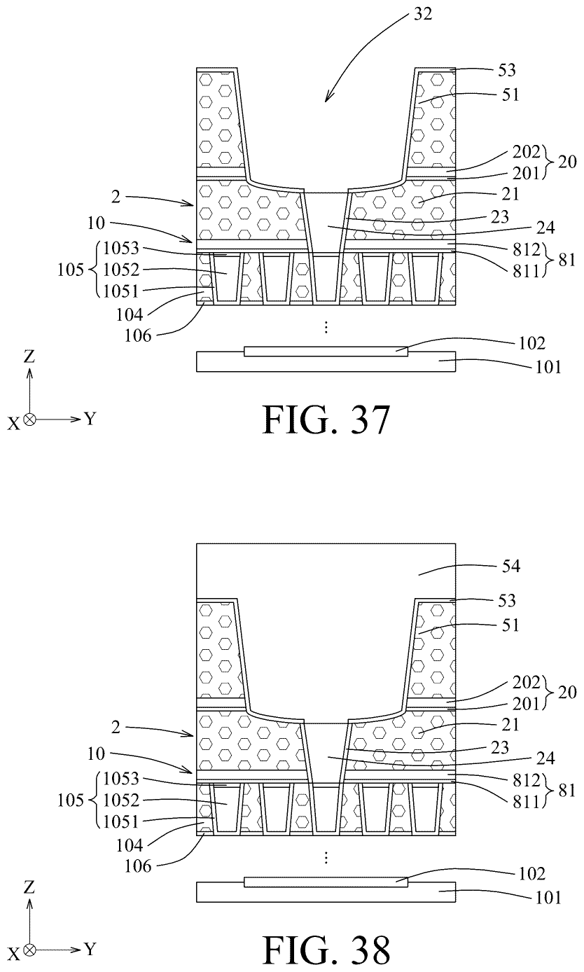

Referring to FIG. 37, after the barrier layer 53 is formed, the second blocking film 33 (see FIG. 36) is removed by a removing process. Suitable processes for removing the second blocking film 33 (see FIG. 36) are similar to those for removing the second blocking film 33 described with reference to FIG. 14, and thus details thereof are omitted for the sake of brevity. At this time, the lower conductive feature 24 is exposed from the barrier layer 53.

Referring to FIG. 38, the upper conductive feature 54 is formed over the barrier 53 to fill the trench 32 (see FIG. 37) and to cover the upper dielectric feature 51. Suitable materials and processes for forming the upper conductive feature 54 are similar to those for forming the upper conductive feature 54 described with reference to FIG. 15, and thus details thereof are omitted for the sake of brevity.

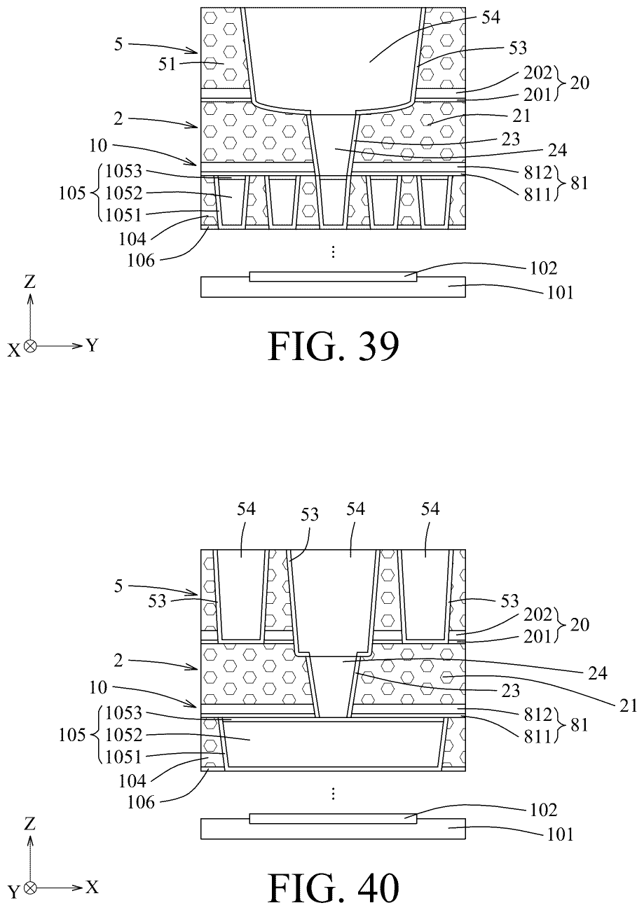

Referring to FIG. 39, a planarization process (e.g., CMP) is performed on the upper conductive feature 54. After the planarization process, the upper interconnect layer 5 is formed, and includes the upper dielectric feature 51, the barrier layer 53 and the upper conductive feature 54. In some embodiments, the upper dielectric feature 51 is still thicker than the lower dielectric feature 21. In addition, at this time, the upper dielectric feature 51 is exposed from the barrier layer 53 and the upper conductive feature 54, the barrier layer 53 is exposed from the upper conductive feature 54, and the upper interconnect layer 5 has the planarized upper surface. It is noted that, the interconnect structure may include a plurality of upper conductive features 54 and a plurality of barrier layers 53. FIG. 39 is a schematic sectional view (a Y-cut view) illustrating one of the upper conductive features 54 in accordance with some embodiments. FIG. 40 is a schematic sectional view (an X-cut view) illustrating the upper conductive features 54 in accordance with some embodiments.

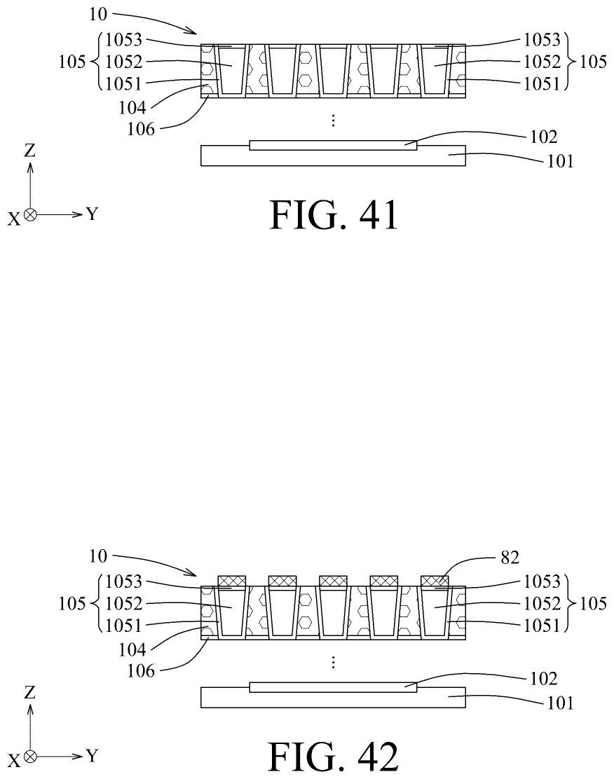

FIGS. 41 to 46 are each a Y-cut or an X-cut view, and illustrate possible intermediate stages of the method depicted in FIG. 1 in accordance with some embodiments. The intermediate stages shown in FIGS. 41 to 44 are provided to describe an approach of forming the lower dielectric feature 21 and the etch stop layer 81 over the base structure 10. Such approach is different from that described with reference to FIG. 3.

Referring to FIG. 41, the base structure 10, before forming the lower dielectric feature 21 and the etch stop layer 81 (see FIG. 3), is illustrated. At this time, the metal caps 1053 of the conductive features 105 and the dielectric layer 104 are exposed to an external environment.

Referring to FIG. 42, the base blocking film 82 is formed over each of the metal caps 1053 of the conductive features 105, while the dielectric layer 104 is exposed from the base blocking film 82. Suitable materials and processes for forming the base blocking film 82 are similar to those for forming the base blocking film 82 described with reference to FIG. 4, and thus the details thereof are omitted for the sake of brevity. Based on the material(s) of the barrier 1051 of each of the conductive features 105 and the material(s) of the base blocking film 82, the base blocking film 82 may be formed to cover the barrier 1051 of each of the conductive features 105 or not. In some embodiments, as shown in FIG. 42, the barrier 1051 of each of the conductive features 105 is exposed from the base blocking film 82.

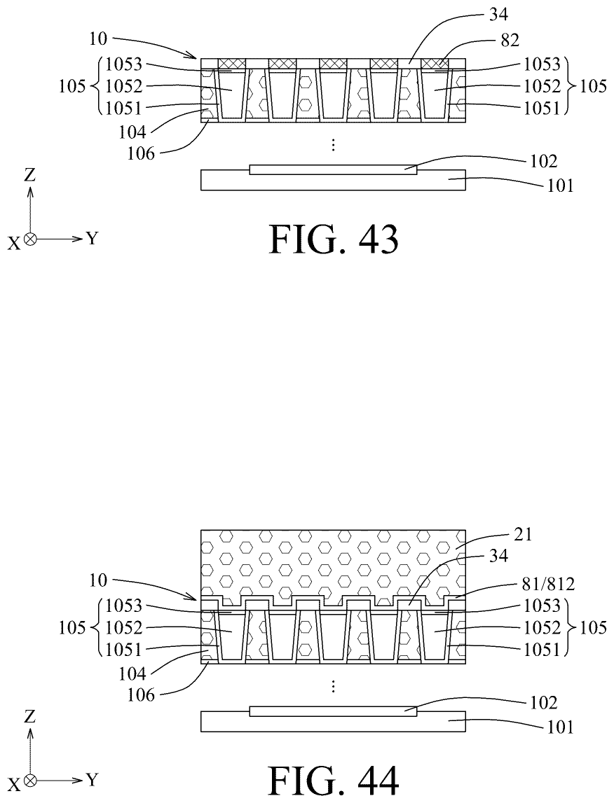

Referring to FIG. 43, a dielectric layer 34 is formed over (i.e., formed on) the dielectric layer 104, while the base blocking film 82 is exposed from the dielectric layer 34. In this case, the base blocking film 82 serves as an inhibitor for preventing the dielectric layer 34 to be formed thereon. Suitable materials and processes for forming the dielectric layer 34 are similar to those for forming the dielectric layer 31 described with reference to FIG. 9, and thus the details thereof are omitted for the sake of brevity.

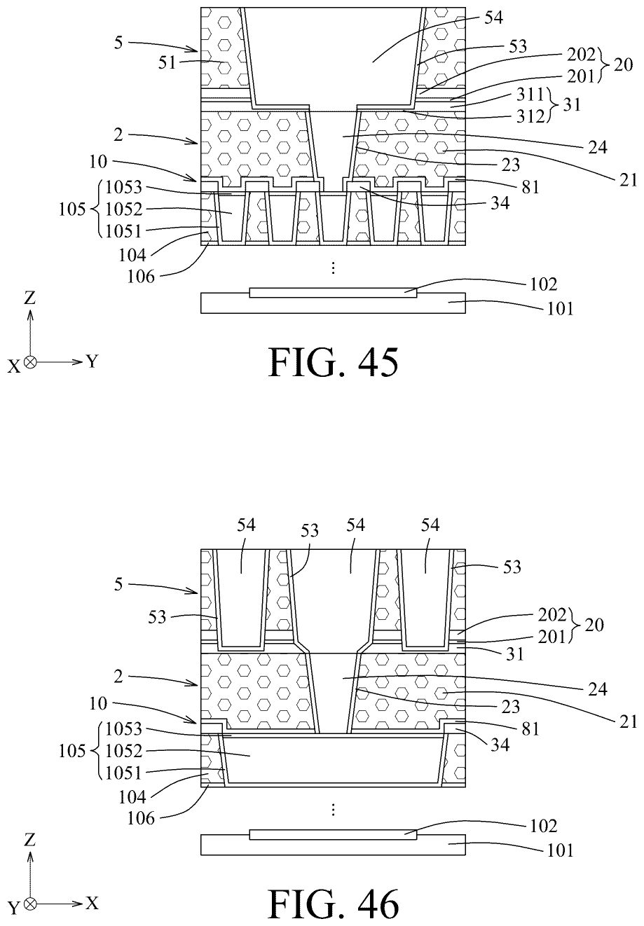

Referring to FIG. 44, the base blocking film 82 (see FIG. 43) is removed by a removing process. Suitable processes for removing the base blocking film 82 (see FIG. 243) are similar to those for removing the base blocking film 82 described with reference to FIGS. 4 and 5, and thus details thereof are omitted for the sake of brevity. At this time, each of the metal caps 1053 of the conductive features 105 is exposed from the dielectric layer 34. Thereafter, the etch stop layer 81 is formed over the metal caps 1053 and the dielectric layer 31 to cover the metal caps 1053 and the dielectric layer 34. The etch stop layer 81 may have a single-layer structure or a multi-layer structure. In some embodiments, the etch stop layer 81 may have the single-layer structure and include the etch stop sublayer 812. Suitable materials and processes for forming the etch stop sublayer 812 are similar to those for forming any one of the etch stop sublayers 811, 812 described with reference to FIG. 3 and thus details thereof are omitted for the sake of brevity. In some other embodiments, the etch stop layer 81 may have the multi-layer structure as shown in FIG. 3. Then, the lower dielectric feature 21 is formed over the etch stop layer 81 (i.e., the lower dielectric feature 21 is formed over the etch stop layer 81 and the dielectric layer 34 opposite to the base structure 10 to cover the etch stop layer 20 and the dielectric layer 31). At this time, the dielectric layer 34 is disposed between the lower dielectric feature 21 and the dielectric layer 104. Suitable materials and processes for forming the lower dielectric feature 21 are similar to those for forming the lower dielectric feature 21 described with reference to FIG. 3, and thus details thereof are omitted for the sake of brevity. When the structure shown in FIG. 44 is processed by the steps illustrated in FIGS. 4 to 16, the structure has a configuration as shown in FIGS. 45 and 46. FIG. 45 is a schematic sectional view (a Y-cut view) illustrating one of the upper conductive features 54 in accordance with some embodiments. FIG. 46 is a schematic sectional view (an X-cut view) illustrating the upper conductive features 54 in accordance with some embodiments.

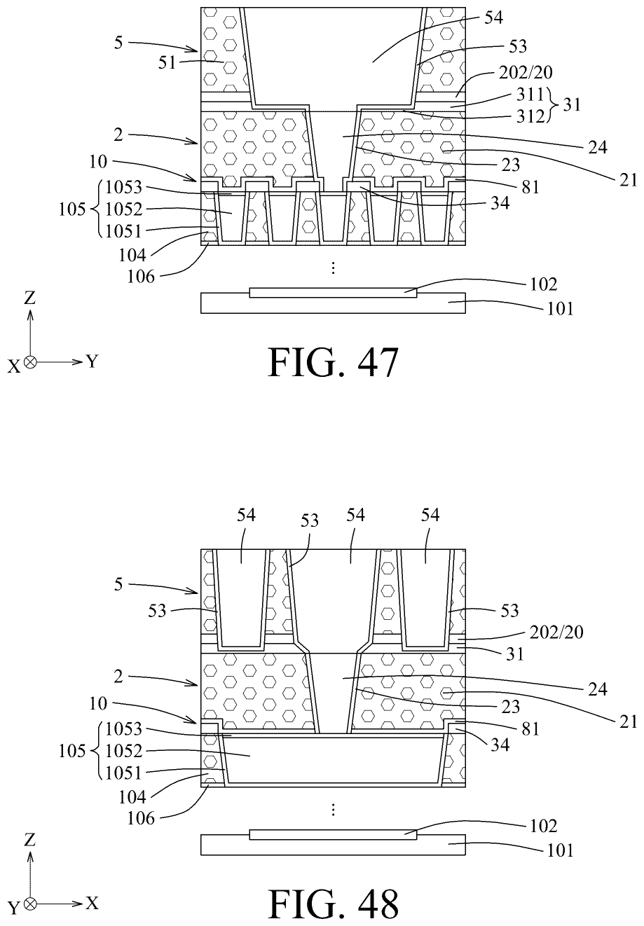

In addition, when the structure shown in FIG. 44 is processed by the steps illustrated in FIGS. 4 to 7, and 19 to 28, the structure has another configuration as shown in FIGS. 47 and 48. FIG. 47 is a schematic sectional view (a Y-cut view) illustrating one of the upper conductive features 54 in accordance with some embodiments. FIG. 48 is a schematic sectional view (an X-cut view) illustrating the upper conductive features 54 in accordance with some embodiments.

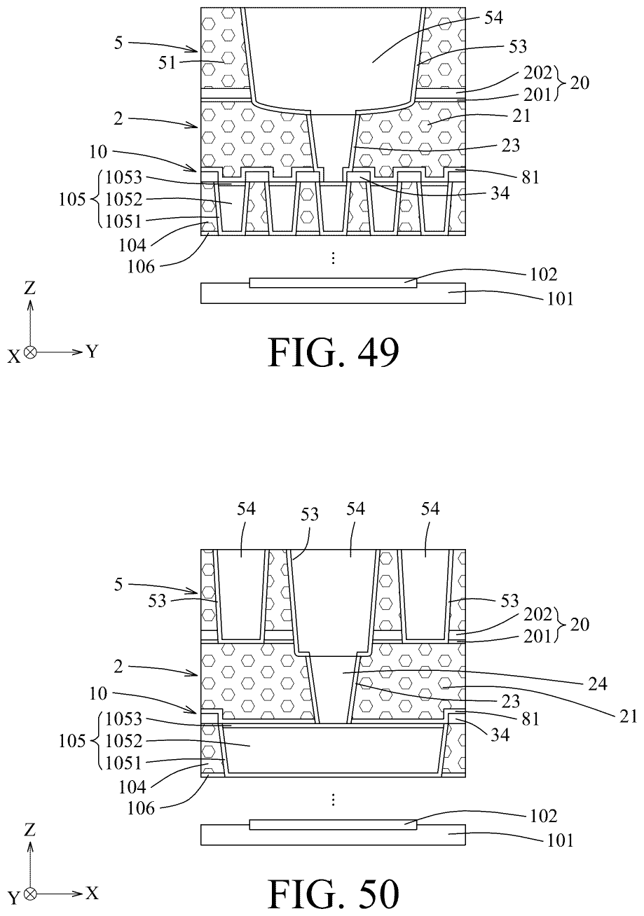

Moreover, when the structure shown in FIG. 44 is processed by the steps illustrated in FIGS. 4 to 7, 19, and 30 to 39, the structure has still another configuration as shown in FIGS. 49 and 50. FIG. 49 is a schematic sectional view (a Y-cut view) illustrating one of the upper conductive features 54 in accordance with some embodiments. FIG. 50 is a schematic sectional view (an X-cut view) illustrating the upper conductive features 54 in accordance with some embodiments.

Step S01 in the flow diagram shown in FIG. 1 is exemplified by the structures shown in FIGS. 3 to 7. FIGS. 41 to 44 illustrate some possible intermediate stages of step S01 in accordance with some embodiments. Step S02 in the flow diagram shown in FIG. 1 is exemplified by the structures shown in FIGS. 8 to 9, 19 to 21, and 30 to 31. Step S03 in the flow diagram shown in FIG. 1 is exemplified by the structures shown in FIGS. 10, 22, and 32. Step S04 in the flow diagram shown in FIG. 1 is exemplified by the structures shown in FIGS. 11, 23, and 33 to 34. Step S05 in the flow diagram shown in FIG. 1 is exemplified by the structures shown in FIGS. 12 to 18, 24 to 29, and 35 to 40. FIGS. 45 to 50 illustrate some other possible interconnect structures obtained in step S05 in accordance with some embodiments.

In summary, by virtue of the first blocking film 30 (see FIGS. 8, 9, 20, 21, 30, and 31) selectively formed on one of the lower conductive feature 24 and the lower dielectric feature 21, the dielectric layer 31 (see FIGS. 16, 17, 28, 29, and 45 to 48) may be provided for protecting the lower dielectric feature 21 during patterning of the upper dielectric feature 51. To be specific, even when the transistor and conductive feature pitch scale down, the lower dielectric feature 21 may be prevented from being undesirably damaged when patterning the upper dielectric feature 51 (e.g., a V-shaped groove (not shown) etched into the lower dielectric feature 21 may be prevented). Therefore, the interconnect structure may be relatively robust, and the undesirable parasitic capacitance (e.g., due to a downwardly extending portion of the upper conductive feature (not shown) formed in the V-shaped groove) may be effectively alleviated. In addition, by virtue of the second blocking film 33 (see FIGS. 12-13, 24-25, and 35-36) selectively formed on the lower conductive feature 24, the barrier layer 53 can be prevented from being formed between the upper conductive feature 54 and the lower conductive feature 24. As such, a contact resistance between the conductive features 24, 54 and an electrical resistance of each of the conductive feature 24, 54 may be greatly reduced. Moreover, since each of the conductive features 24, 54 is formed using a single damascene process, the aspect ratio of each of the trenches 22, 32 (see FIGS. 4, 11, 23, and 33) for filling the material(s) for forming the respective conductive feature 24 or 54 is relatively small. Thus, the trench-filling difficulties due to a high aspect ratio of the trenches used in the dual damascene process may be overcome. Furthermore, by virtue of the base blocking film 82 (see FIGS. 4 and 42), a metal via (e.g., the lower conductive feature 24) may be more precisely aligned with a metal line (e.g., one of the conductive features 105), and thus the overlay shift issue may be prevented.

In accordance with some embodiments of the present disclosure, a method for manufacturing an interconnect structure includes: forming a lower interconnect layer over a base structure, the lower interconnect layer including a lower dielectric feature and a lower conductive feature disposed in the lower dielectric feature; forming a dielectric layer on one of the lower conductive feature and the lower dielectric feature, while the other one of the lower conductive feature and the lower dielectric feature is exposed from the dielectric layer, a material of the dielectric layer being different from a material of the lower dielectric feature; after forming the dielectric layer, forming an upper dielectric feature over the lower interconnect layer to cover the dielectric layer, the upper dielectric feature being thicker than the lower dielectric feature, a material of the upper dielectric feature being different from the material of the dielectric layer; performing a patterning process to form a trench in the upper dielectric feature, to etch the dielectric layer, and to expose an upper surface of the lower conductive feature; and forming an upper conductive feature in the trench.

In accordance with some embodiments of the present disclosure, the dielectric layer includes aluminum, hafnium, zirconium, titanium, yttrium, or combinations thereof.

In accordance with some embodiments of the present disclosure, the dielectric layer has a dielectric constant ranging from 4 to 20.

In accordance with some embodiments of the present disclosure, in forming the dielectric layer, the dielectric layer is formed on the lower dielectric feature, while the lower conductive feature is exposed from the dielectric layer.

In accordance with some embodiments of the present disclosure, in the patterning process, the dielectric layer has a non-etched portion covered by the upper dielectric feature, and an etched portion exposed from the trench, and a thickness of the etched portion is less than a thickness of the non-etched portion.

In accordance with some embodiments of the present disclosure, after the patterning process and prior to forming the upper conductive feature, the lower dielectric feature is covered by the etched portion.

In accordance with some embodiments of the present disclosure, in forming the dielectric layer, the dielectric layer is formed on the lower conductive feature, while the lower dielectric feature is exposed from the dielectric layer.

In accordance with some embodiments of the present disclosure, the patterning process includes forming the trench in the upper dielectric feature to expose the dielectric layer; and etching the dielectric layer to expose the upper surface of the lower conductive feature.

In accordance with some embodiments of the present disclosure, a method for manufacturing an interconnect structure includes: forming a lower interconnect layer over a base structure that is formed with a plurality of transistors, the lower interconnect layer including a lower conductive feature and a lower dielectric feature; forming a first blocking film over one of the lower conductive feature and the lower dielectric feature, while the other one of the lower conductive feature and the lower dielectric feature is exposed from the first blocking film; after forming the first blocking film, forming a dielectric layer over the other one of the lower conductive feature and the lower dielectric feature, while the first blocking film is exposed from the dielectric layer, a material of the dielectric layer being different from a material of the lower dielectric feature; after forming the dielectric layer, removing the first blocking film; after removing the first blocking film, forming an etch stop layer over the lower interconnect layer to cover the dielectric layer, a material of the etch stop layer being different from each of the material of the dielectric layer and the material of the lower dielectric feature; forming an upper dielectric feature over the etch stop layer, the upper dielectric feature being thicker than the lower dielectric feature, a material of the upper dielectric feature being different from the material of the dielectric layer; performing a patterning process to form a trench in the upper dielectric feature, to etch the etch stop layer and the dielectric layer, and to expose an upper surface of the lower conductive feature; and forming an upper conductive feature in the trench.

In accordance with some embodiments of the present disclosure, a width of the trench is greater than a width of the lower conductive feature.

In accordance with some embodiments of the present disclosure, a bottommost point in the trench is at a level not lower than a level of the upper surface of the lower conductive feature.

In accordance with some embodiments of the present disclosure, the dielectric layer includes aluminum, aluminum oxide, aluminum oxycarbide, aluminum oxynitride, aluminum oxycarbonitride, aluminum silicate, silicon aluminum oxynitride, aluminum silicon oxycarbonitride, hafnium nitride, hafnium oxynitride, hafnium silicate, hafnium silicon oxynitride, hafnium silicon oxycarbide, hafnium silicon oxycarbonitride, zirconium silicate, zirconium silicon oxycarbide, zirconium silicon oxycarbonitride, titanium oxynitride, titanium silicate, titanium silicon oxycarbide, titanium oxycarbide, yttrium silicate, yttrium silicon oxycarbide, yttrium silicon oxycarbonitride, or combinations thereof.

In accordance with some embodiments of the present disclosure, forming the upper conductive feature includes forming a second blocking film over the upper surface of the lower conductive feature, while an inner surface of the trench, except the upper surface of the lower conductive feature, is exposed from the second blocking film; after forming the second blocking film, forming a barrier layer over an inner surface of the upper dielectric feature, while the second blocking film is exposed from the barrier layer; after forming the barrier layer, removing the second blocking film; and after removing the second blocking film, forming the upper conductive feature in the trench.

In accordance with some embodiments of the present disclosure, the first blocking film is formed over the lower conductive feature, and the dielectric layer is formed over the lower dielectric feature.

In accordance with some embodiments of the present disclosure, the first blocking film includes a thiol-based compound, an acid-based compound, a bicyclic nitrogen heterocycle compound, or combinations thereof.

In accordance with some embodiments of the present disclosure, the first blocking film includes dodecanethiol, alkanethiol, phosphonic acid, octadecylphosphonic acid, benzotriazole, or combinations thereof.

In accordance with some embodiments of the present disclosure, the first blocking film is formed over the lower dielectric feature, and the dielectric layer is formed over the lower conductive feature.

In accordance with some embodiments of the present disclosure, the first blocking film includes a silane-based compound.

In accordance with some embodiments of the present disclosure, the first blocking film includes octadecyltrichlorosilane, octadecyltrimethoxysilane, (3-aminopropyl)triethoxysilane, butyltriethoxysilane, cyclohexyltrimethoxysilane, cyclopentyltrimethoxysilane, dodecyltriethoxysilane, dodecyltrimethoxysilane, decyltriethoxysilane, dimethoxy(methyl)-n-octylsilane, triethoxyethylsilane, ethyltrimethoxysilane, hexyltrimethoxysilane, hexyltriethoxysilane, hexadecyltrimethoxysilane, hexadecyltriethoxysilane, triethoxymethylsilane, or combinations thereof.

In accordance with some embodiments of the present disclosure, an interconnect structure includes: a lower interconnect layer disposed over a base structure including at least one transistor that includes a gate dielectric layer, the lower interconnect layer including a lower conductive feature and a lower dielectric feature, a dielectric constant of the lower dielectric feature being less than a dielectric constant of the gate dielectric layer; an upper interconnect layer disposed over the lower interconnect layer opposite to the base structure, the upper interconnect layer including an upper conductive feature and an upper dielectric feature; and a dielectric layer disposed between the lower interconnect layer and the upper interconnect layer, the dielectric layer having a first portion disposed between the upper dielectric feature and the lower dielectric feature, and a second portion disposed between the upper conductive feature and the lower dielectric feature, a thickness of the second portion being less than a thickness of the first portion.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an interconnect structure, comprising:
forming a lower interconnect layer over a base structure, the lower interconnect layer including a lower dielectric feature and a lower conductive feature disposed in the lower dielectric feature;
forming a dielectric layer on one of the lower conductive feature and the lower dielectric feature, while the other one of the lower conductive feature and the lower dielectric feature is exposed from the dielectric layer, a material of the dielectric layer being different from a material of the lower dielectric feature;
after forming the dielectric layer, forming an upper dielectric feature over the lower interconnect layer to cover the dielectric layer, the upper dielectric feature being thicker than the lower dielectric feature, a material of the upper dielectric feature being different from the material of the dielectric layer;
performing a patterning process to form a trench in the upper dielectric feature, to etch the dielectric layer, and to expose an upper surface of the lower conductive feature; and
forming an upper conductive feature in the trench.

2. The method of claim 1, wherein the dielectric layer includes aluminum, hafnium, zirconium, titanium, yttrium, or combinations thereof.

3. The method of claim 1, wherein the dielectric layer has a dielectric constant ranging from 4 to 20.

4. The method of claim 1, wherein, in forming the dielectric layer, the dielectric layer is formed on the lower dielectric feature, while the lower conductive feature is exposed from the dielectric layer.

5. The method of claim 4, wherein, in the patterning process,
the dielectric layer has a non-etched portion covered by the upper dielectric feature, and an etched portion exposed from the trench, and
a thickness of the etched portion is less than a thickness of the non-etched portion.

6. The method of claim 5, wherein, after the patterning process and prior to forming the upper conductive feature,
the lower dielectric feature is covered by the etched portion.

7. The method of claim 1, wherein, in forming the dielectric layer, the dielectric layer is formed on the lower conductive feature, while the lower dielectric feature is exposed from the dielectric layer.

8. The method of claim 7, wherein the patterning process includes:
forming the trench in the upper dielectric feature to expose the dielectric layer; and
etching the dielectric layer to expose the upper surface of the lower conductive feature.

9. A method for manufacturing an interconnect structure, comprising:
forming a lower interconnect layer over a base structure that is formed with a plurality of transistors, the lower interconnect layer including a lower conductive feature and a lower dielectric feature;
forming a first blocking film over one of the lower conductive feature and the lower dielectric feature, while the other one of the lower conductive feature and the lower dielectric feature is exposed from the first blocking film;
after forming the first blocking film, forming a dielectric layer over the other one of the lower conductive feature and the lower dielectric feature, while the first blocking film is exposed from the dielectric layer, a material of the dielectric layer being different from a material of the lower dielectric feature;
after forming the dielectric layer, removing the first blocking film;
after removing the first blocking film, forming an etch stop layer over the lower interconnect layer to cover the dielectric layer, a material of the etch stop layer being different from each of the material of the dielectric layer and the material of the lower dielectric feature;
forming an upper dielectric feature over the etch stop layer, the upper dielectric feature being thicker than the lower dielectric feature, a material of the upper dielectric feature being different from the material of the dielectric layer;
performing a patterning process to form a trench in the upper dielectric feature, to etch the etch stop layer and the dielectric layer, and to expose an upper surface of the lower conductive feature; and
forming an upper conductive feature in the trench.

10. The method of claim 9, wherein a width of the trench is greater than a width of the lower conductive feature.

11. The method of claim 9, wherein a bottommost point in the trench is at a level not lower than a level of the upper surface of the lower conductive feature.

12. The method of claim 9, wherein the dielectric layer includes aluminum, aluminum oxide, aluminum oxycarbide, aluminum oxynitride, aluminum oxycarbonitride, aluminum silicate, silicon aluminum oxynitride, aluminum silicon oxycarbonitride, hafnium nitride, hafnium oxynitride, hafnium silicate, hafnium silicon oxynitride, hafnium silicon oxycarbide, hafnium silicon oxycarbonitride, zirconium silicate, zirconium silicon oxycarbide, zirconium silicon oxycarbonitride, titanium oxynitride, titanium silicate, titanium silicon oxycarbide, titanium oxycarbide, yttrium silicate, yttrium silicon oxycarbide, yttrium silicon oxycarbonitride, or combinations thereof.

13. The method of claim 9, wherein forming the upper conductive feature includes:
forming a second blocking film over the upper surface of the lower conductive feature, while an inner surface of the trench, except the upper surface of the lower conductive feature, is exposed from the second blocking film;
after forming the second blocking film, forming a barrier layer over an inner surface of the upper dielectric feature, while the second blocking film is exposed from the barrier layer;
after forming the barrier layer, removing the second blocking film; and
after removing the second blocking film, forming the upper conductive feature in the trench.

14. The method of claim 9, wherein the first blocking film is formed over the lower conductive feature, and the dielectric layer is formed over the lower dielectric feature.

15. The method of claim 14, wherein the first blocking film includes a thiol-based compound, an acid-based compound, a bicyclic nitrogen heterocycle compound, or combinations thereof.

16. The method of claim 14, wherein the first blocking film includes dodecanethiol, alkanethiol, phosphonic acid, octadecylphosphonic acid, benzotriazole, or combinations thereof.

17. The method of claim 9, wherein the first blocking film is formed over the lower dielectric feature, and the dielectric layer is formed over the lower conductive feature.

18. The method of claim 17, wherein the first blocking film includes a silane-based compound.

19. The method of claim 17, wherein the first blocking film includes octadecyltrichlorosilane, octadecyltrimethoxysilane, (3-aminopropyl)triethoxysilane, butyltriethoxysilane, cyclohexyltrimethoxysilane, cyclopentyltrimethoxysilane, dodecyltriethoxysilane, dodecyltrimethoxysilane, decyltriethoxysilane, dimethoxy(methyl)-n-octylsilane, triethoxyethylsilane, ethyltrimethoxysilane, hexyltrimethoxysilane, hexyltriethoxysilane, hexadecyltrimethoxysilane, hexadecyltriethoxysilane, triethoxymethylsilane, or combinations thereof.

20. An interconnect structure, comprising:
a lower interconnect layer disposed over a base structure including at least one transistor that includes a gate dielectric layer, the lower interconnect layer including a lower conductive feature and a lower dielectric feature, a dielectric constant of the lower dielectric feature being less than a dielectric constant of the gate dielectric layer;
an upper interconnect layer disposed over the lower interconnect layer opposite to the base structure, the upper interconnect layer including an upper conductive feature and an upper dielectric feature; and
a dielectric layer disposed between the lower interconnect layer and the upper interconnect layer, the dielectric layer having a first portion disposed between the upper dielectric feature and the lower dielectric feature, and a second portion disposed between the upper conductive feature and the lower dielectric feature, a thickness of the second portion being less than a thickness of the first portion.
